(19) United States
(12) Patent Application Publication
(10) Pub. No.: US 2024/0409690 A1
(43) Pub. Date: Dec. 12, 2024

(54) DEGRADABLE POLYIMIDES FOR FLEXIBLE ELECTRONIC SUBSTRATES USING THIOL-ENE CLICK CHEMISTRY

(71) Applicant: University of Utah Research Foundation, Salt Lake City, UT (US)

(72) Inventors: Caleb Reese, Salt Lake City, UT (US); Chen Wang, Salt Lake City, UT (US)

(21) Appl. No.: 18/737,657

(22) Filed: Jun. 7, 2024

Related U.S. Application Data
(60) Provisional application No. 63/507,272, filed on Jun. 9, 2023.

(51) Int. Cl. C08G 75/045; C08G 73/12; H01L 21/48; H01L 21/56; H01L 23/538

(52) U.S. Cl. CPC C08G 75/045; C08G 73/128; H01L 21/4857; H01L 21/56; H01L 23/5387; C08G 2230/00

(57) ABSTRACT

Disclosed herein is a degradable polyimide substrate that may be reliably used as an electronic substrate in flexible electronics. The degradable polyimide substrate is formed via thiol-ene click chemistry reactions between diallyl imide or other alkene monomers and thiol monomers, that can be activated by photoirradiation at relatively low temperatures (e.g., about 80° C.). As a result, the degradable polyimide substrates disclosed herein may be cured using a simple, energy efficient curing process that allows for streamlined manufacturing of circuits including multilayered circuits. In some instances, epoxy monomers may be added to the monomer resin used to form the polyimide substrate, wherein selective curing may yield polymer substrates with varying degrees of flexibility and rigidity.

### CROSS-REFERENCE TO RELATED APPLICATIONS

This application claims the benefit of and priority to U.S. Provisional Patent Application Ser. No. 63/507,272 filed on Jun. 9, 2023, and entitled “DEGRADABLE POLYIMIDES FOR FLEXIBLE ELECTRONIC SUBSTRATES USING THIOL-ENE CLICK CHEMISTRY,” which application is expressly incorporated herein by reference in its entirety.

### STATEMENT REGARDING FEDERALLY SPONSORED RESEARCH OR DEVELOPMENT

N/A.

### FIELD OF THE INVENTION

The present invention generally relates to degradable polymers for use as substrates for flexible electronics. For example, more specifically, an embodiment of the invention relates to polyimide films for flexible electronic substrates that can be synthesized with UV light, e.g., for formation of unique shapes that can be easily degraded to recycle particular metals and polymers used for electronic devices.

### BACKGROUND

Dupont Kapton® is the industry standard polyimide electronic substrate but requires high heat to polymerize and does not easily degrade, making extraction of precious metals embedded in films of Kapton® difficult. As a result, existing flexible electronic substrates are rarely recycled. This has led to global accumulation of electronic waste (e-waste). 2019 alone produced about 54 million tons of e-waste, averaging 7.3 kg per person. The continued development of flexible electronics, (i.e., thin, flexible devices made on compliant substrates) seems inevitable—these devices offer promising opportunities in robotics, wearables, health monitoring, packaging, and the Internet of Things. Unfortunately, the continued adoption of flexible electronics and other low-cost single-use or otherwise relatively disposable electronics only worsens the dire e-waste situation.

Therefore, there remains a need to develop new polymeric electronic substrates (e-substrates) with built-in reprocessability via chemical, thermal, or biological means. While some polymer substances have been studied for use as reprocessable electronic substrates, these substances do not possess the necessary physical, chemical, and electrical properties that allow for reliable integration into flexible electronics.

### SUMMARY

The present disclosure relates to using thiol-ene polymerization with degradable thiol linkages combined with high performance imide linkages to make a polymer that can be processed with light (e.g., UV or visible light), heat, and/or thermal radical generating catalysts into many shapes and form factors. Once the polymer has finished its life cycle, the degradable linkages can be degraded at room temperature to yield base monomer units that can be used to form similar polymers again.

In one embodiment, a degradable polyimide substrate formed from diallyl imide or other difunctional alkene monomers and thiol monomers, with thioether linkages between the diallyl imide or other difunctional alkene monomers and the thiol monomers, wherein the diallyl imide or other difunctional alkene monomers and the thiol monomers polymerize to form the polyimide substrate. The thiol monomers may comprise ester linkages, wherein the ester linkages are degradable under mild conditions.

In some embodiments, the difunctional imide monomers comprise monomers with functional groups including one or more of ether, diether, cyclohexane, hexafluoro, ester, cyclobutene, phenome, pyromellitic, or imide ester monomers. In some embodiments, these difunctional imide monomers may contain reactive groups including allyl, alkene, acrylate, methacrylate, epoxy, thiol, norbornene, and/or bisimides. In some embodiments, the thiol monomers may comprise trimethylolpropane tris 3-mercaptopropionate (TMPMP), ethylene glycol di(3-mercaptopropionate) (GDMP), and/or pentaerythritol tetra(3-mercaptopropionate) (PETMP).

In some embodiments, the polymer substrate may be degraded using a transesterification reaction stimulated at or near ambient temperatures (e.g., no more than about 60° C., less than about 55° C., less than about 50° C., less than about 45° C., less than about 40° C., less than about 35° C., or less than about 30° C., such as from about 10° C. to about 30° C., or from about 15° C. to about 25° C.). Such a reaction may be stimulated with a methanol or other alcohol solution. Higher temperatures may also be used, e.g., when using an alcohol other than methanol (e.g., which boils at about 60° C.). For example, any temperature up to the boiling point of the selected alcohol may be used. Dichloromethane (DCM) may also be included, e.g., at about 50% by weight, e.g., to speed up the degradation. An alkali metal carbonate such as potassium carbonate (K₂CO₃), sodium carbonate, an alkali metal hydroxide such as potassium hydroxide or sodium hydroxide, or an organic base such as triethylamine may be used as a catalyst.

The degradable polyimide substrates disclosed herein have suitable physical, thermal, and electrical properties for use as an electronic substrate, particularly a flexible electronics substrate. For example, the polymer substrate may have a glass transition temperature from about −100° C. to about 250° C., from about −50° C. to about 200° C., from about 50° C. to about 150° C., or from about 60° C. to about 100° C. The polymer substrate may have a tensile strength of at least about 30 mPa, at least about 35 MPa, at least about 40 MPa, or at least about 45 MPa, no more than about 100 MPa, no more than about 80 MPa, or no more than about 75 MPa.

A method of synthesizing and curing the degradable polyimide substrate involves providing the diallyl imide or other difunctional alkene monomers and the thiol monomers, heating the monomers to form a liquid resin comprising melted diallyl imide or other difunctional alkene monomers and melted thiol monomers, transferring the liquid resin to molds (e.g., heated molds), and curing the liquid resin with UV or visible light. Because of the relatively low melting point of the diallyl imide or other difunctional alkene monomers and the thiol monomers, the liquid resin may remain liquid for an amount of time sufficient to transfer the liquid resin to the heated molds. By way of example, the monomers may have a melting point less than about 220° C., less than about 200° C., less than about 150° C., or less than about 100° C. In an embodiment, one or more of the selected monomers may be liquid under ambient conditions (e.g., melting point of less than about 30° C., 25° C., or 20° C.)

In some embodiments, diallyl imide monomers or other difunctional alkene and thiol monomers, together with epoxy monomers may be used to form a multimodulus polymer substrate. The multimodulus polymer substrate can be formed from the diallyl imide or other difunctional alkene monomers, thiol monomers, and epoxy monomers, with thioether linkages between the diallyl imide or other difunctional alkene polymerization residues and the thiol residues, with thiol-epoxy linkages between the thiol residues and the epoxy residues, and with epoxy-epoxy linkages between the epoxy residues. The thiol-epoxy linkages result in a more flexible polymer substrate and the epoxy-epoxy linkages result in a relatively more firm substrate. As such, the substrate may be describes as a multimodulus polymer substrate.

A method of synthesizing and curing the multimodulus polymer substrate involves providing diallyl imide or other difunctional alkene monomers, thiol monomers, and epoxy monomers, heating the monomers to produce a liquid resin comprising melted diallyl imide or other difunctional alkene, thiol, and epoxy monomers, photo curing the resin with a photodosage of UV or visible light to form the thioether linkages between the diallyl imide or other difunctional alkene monomers and the thiol monomers, thermal curing the resin at a first temperature (e.g., about 80° C.) to form the thiol-epoxy linkages between the thiol monomers and the epoxy monomers, and thermal curing the resin at a second temperature (e.g., about 120° C.) to form the epoxy-epoxy linkages between epoxy monomers. Varying the photodosage of UV or visible light varies the amount of unreacted thiol groups in the resin during the first thermal curing step, and the amount of unreacted thiol groups in the resin varies the amount of unreacted epoxy groups in the resin during the second thermal curing step. Thus the photodosage used in the photocuring step determines the proportion of thioether linkages formed in the photocuring step, thiol-epoxy linkages formed in the first thermal curing step, and the amount of epoxy-epoxy linkages formed in the second thermal curing step. For example, a relatively low photodosage (from about 0 mJ/cm² to about 70 mJ/cm²) may produce a relatively flexible polymer substrate. A relatively high photodosage (about 70 mJ/cm² to about 175 mJ/cm²) may produce a relatively firm or stiff polymer substrate. In other words, adjusting the photodosage during either or both of the thermal curing steps may be used to adjust the stiffness versus flexibility characteristics of the formed polymer substrate.

The disclosed embodiments may be utilized to manufacture flexible electronics due to their desirable physical, thermal, and electrical properties. A method of manufacturing flexible electronics (e.g., circuits) using the polymer substrates disclosed herein may involve depositing and curing a first degradable polyimide film, depositing electronic components on the first degradable polyimide film, the electronic components forming a circuit, and depositing and curing a second degradable polyimide film on top of the electronic components. Such steps are repeatable to form a multilayered circuit. Furthermore, the degradable polyimide films can be dissolved without harming the underlying or embedded electronic components.

In some embodiments, such as those where the above method is used to manufacture a multilayered circuit, either or both of the first and second degradable films may be selectively cured. The uncured portions of these films may then be removed to form one or more vias (e.g., an electrical connection or pathway between different layers). A via may connect circuits embedded in different layers of a multilayered circuit.

While principally described in terms of monomers used in forming the described polymers, it will be appreciated that larger polymerizable components can also be used, and are within the scope of the intended meaning of “monomer” or “monomers”. For example, dimers, trimers, oligomers, and other polymerizable components having the described functional groups are also contemplated, and within the scope of the meaning of “monomer” or “monomers”.

In any of the described embodiments, exemplary diallyl imide monomers may comprise at least one of diallyl imide ether monomers, diallyl imide diether monomers, diallyl imide cyclohexane monomers, diallyl imide hexafluoro monomers, or diallyl imide ester monomers. A wide variety of other difunctional alkene imide monomers may also or alternatively be used.

In any of the described embodiments, the one or more thiol monomers may comprise at least one of trimethylolpropane tris 3-mercaptopropionate (TMPMP), ethylene glycol di(3-mercaptopropionate) (GDMP), or pentaerythritol tetra(3-mercaptopropionate) (PETMP).

In any of the described embodiments, any of the employed monomers may have a melting point of less than about 220° C., less than about 200° C., less than about 150° C., or less than about 100° C.

In any of the described embodiments, the polymer substrate may be cross-linked.

In any of the described embodiments, the polymer substrate may have a glass transition temperature from about −100° C. to about 250° C., from about −50° C. to about 200° C., from about 50° C. to about 150° C., or from about 60° C. to about 100° C.

In any of the described embodiments, the polymer substrate may have a Young's modulus of at least about 1000 MPa, at least about 1050 MPa, at least about 1100 MPa, at least about 1150 MPa, no more than about 2500 MPa, no more than about 2000 MPa, no more than about 1500 MPa, no more than about 1400 MPa, no more than about 1300 MPa, or no more than about 1250 MPa.

In any of the described embodiments, the polymer substrate may have a tensile strength of at least about 30 mPa, at least about 35 MPa, at least about 40 MPa, or at least about 45 MPa, no more than about 100 MPa, no more than about 80 MPa, or no more than about 75 MPa.

In any of the described embodiments, the polymer substrate may be degraded using a transesterification reaction stimulated at or near ambient temperature.

In any of the described embodiments, the transesterification reaction may be stimulated with a methanol or other alcohol solution. In an embodiment, some portion of dichloromethane (DCM), e.g., about 50% by weight or volume, may be present in the solution. An alkali metal carbonate or variety of other catalysts, e.g., potassium carbonate (K₂CO₃) may be used during such transesterification.

In any of the described embodiments, the photodosage may be from about 0 mJ/cm² to about 70 mJ/cm², which photodosage may produce a flexible polymer substrate.

In any of the described embodiments, the photodosage may be from about 70 mJ/cm² to about 175 mJ/cm², which may produce a firm or stiff polymer substrate.

In any of the described embodiments, a first degradable film and a second degradable film are selectively cured, and the uncured portions of the first degradable film and the second degradable film can be removed to form one or more electrical vias.

In any of the described embodiments, the one or more electrical vias may connect circuits of different layers of a multilayered circuit.

In any of the described embodiments, the first degradable film and the second degradable film may comprise diallyl imide monomer polymerization residues, thiol monomer polymerization residues, and thioether linkages between the diallyl imide or other difunctional alkene monomer polymerization residues and the thiol monomer polymerization residues, where the diallyl imide monomer or other difunctional alkene monomer polymerization residues and the thiol monomer polymerization residues are polymerized to form the flexible polymer substrate. The thiol monomer polymerization residues may comprise ester linkages which are degradable under mild conditions.

Features from any of the disclosed embodiments may be used in combination with one another, without limitation. This summary is provided to introduce a selection of concepts in a simplified form that are further described below in the detailed description. This summary is not necessarily intended to identify key or essential features of the claimed subject matter, nor is it intended to be used as an indication of the scope of the claimed subject matter.

Additional features and advantages of the disclosure will be set forth in the description which follows, and in part will be obvious from the description, or may be learned by the practice of the disclosure. The features and advantages of the disclosure may be realized and obtained by means of the components and combinations particularly pointed out in the appended claims. These and other features of the present disclosure will become more fully apparent from the following description and appended claims, or may be learned by the practice of the disclosure as set forth hereinafter.

Disclosure of certain features relative to a specific embodiment of the present disclosure should not be construed as limiting application or inclusion of said features to the specific embodiment. Rather, it will be appreciated that other embodiments can also include said features, members, elements, parts, and/or portions without necessarily departing from the scope of the present disclosure. Moreover, unless a feature is described as requiring another feature in combination therewith, any feature herein may be combined with any other feature of a same or different embodiment disclosed herein. Furthermore, various well-known aspects of illustrative systems, methods, apparatus, and the like are not described herein in particular detail in order to avoid obscuring aspects of the example embodiments. Such aspects are, however, also contemplated herein.

### BRIEF DESCRIPTION OF THE DRAWINGS

To further clarify the above and other advantages and features of the present invention, a more particular description of the invention will be rendered by reference to specific embodiments thereof which are illustrated in the drawings located in the specification. It is appreciated that these drawings depict only typical embodiments of the invention and are therefore not to be considered limiting of its scope. The invention will be described and explained with additional specificity and detail through the use of the accompanying drawings.

FIGS. 1A-1J illustrate exemplary monomers that can be used to form a degradable polyimide substrate.

FIG. 2A schematically illustrates an exemplary polymer network of an exemplary polyimide substrate.

FIG. 2B schematically illustrates an exemplary degraded polyimide substrate.

FIG. 3 illustrates an exemplary method of synthesizing and curing a degradable polyimide substrate.

FIG. 4 is a table showing important physical, thermal, and electrical characteristics of several exemplary polyimide substrates.

FIG. 5 illustrates an exemplary method of manufacturing a circuit using a polyimide substrate as an electronics substrate.

FIG. 6 illustrates an exemplary epoxy monomer.

FIG. 7 illustrates an exemplary method of synthesizing and curing a multimodulus polymer substrate.

FIG. 8 illustrates exemplary chemical reactions related to the method of FIG. 7.

FIGS. 9A-9C illustrate the effect of various photodosages during the curing process for exemplary multimodulus polymer substrates.

FIGS. 10A-10C illustrate an exemplary synthesis of polyimide ester (PI ester) wherein FIG. 10A illustrates an exemplary synthesis reaction, FIG. 10B illustrates the proton nuclear magnetic resonance (¹H NMR) spectrum of the product of the synthesis, and FIG. 10C illustrates the carbon nuclear magnetic resonance (¹³C NMR) spectrum of the product of the synthesis.

FIGS. 11A-11C illustrate an exemplary synthesis of polyimide ether (PI ether) wherein FIG. 11A illustrates an exemplary synthesis reaction, FIG. 11B illustrates ¹H NMR spectrum of the product of the synthesis, and FIG. 11C illustrates the ¹³C NMR spectrum of the product of the synthesis.

FIGS. 12A-12C illustrate an exemplary synthesis of polyimide cyclohexane (PI cyclohexane) wherein FIG. 12A illustrates an exemplary synthesis reaction, FIG. 12B illustrates ¹H NMR spectrum of the product of the synthesis, and FIG. 12C illustrates the ¹³C NMR spectrum of the product of the synthesis.

FIGS. 13A-13C illustrate an exemplary synthesis of polyimide diether (PI diether) wherein FIG. 13A illustrates an exemplary synthesis reaction, FIG. 13B illustrates ¹H NMR spectrum of the product of the synthesis, and FIG. 13C illustrates the ¹³C NMR spectrum of the product of the synthesis.

FIGS. 14A-14C illustrate an exemplary synthesis of polyimide hexafluoro (PI hexafluoro) wherein FIG. 12A illustrates an exemplary synthesis reaction, FIG. 12B illustrates ¹H NMR spectrum of the product of the synthesis, and FIG. 12C illustrates the ¹³C NMR spectrum of the product of the synthesis.

FIG. 15 schematically illustrates an exemplary synthesis of a degradable polyimide substrate.

### DETAILED DESCRIPTION

### Definitions

Before describing the present invention in detail, it is to be understood that this invention is not limited to particularly exemplified systems or process parameters that may, of course, vary. It is also to be understood that the terminology used herein is for the purpose of describing particular embodiments of the invention only, and is not intended to limit the scope of the invention in any manner.

All publications, patents and patent applications cited herein, whether supra or infra, are hereby incorporated by reference in their entirety to the same extent as if each individual publication, patent or patent application was specifically and individually indicated to be incorporated by reference.

The term “comprising” which is synonymous with “including,” “containing,” or “characterized by,” is inclusive or open-ended and does not exclude additional, unrecited elements or method steps.

The term “consisting essentially of” limits the scope of a claim to the specified materials or steps “and those that do not materially affect the basic and novel characteristic(s)” of the claimed invention.

The term “consisting of” as used herein, excludes any element, step, or ingredient not specified in the claim.

It must be noted that, as used in this specification and the appended claims, the singular forms “a,” “an” and “the” include plural referents unless the content clearly dictates otherwise. Thus, for example, reference to a “monomer” includes one, two or more monomers.

Unless otherwise stated, all percentages, ratios, parts, and amounts used and described herein are by weight.

Numbers, percentages, ratios, or other values stated herein may include that value, and also other values that are about or approximately the stated value, as would be appreciated by one of ordinary skill in the art. As such, all values herein are understood to be modified by the term “about” or its synonyms such as “approximately” or “substantially.” Such values thus include an amount or state close to the stated amount or state that still performs a desired function or achieves a desired result. A stated value should therefore be interpreted broadly enough to encompass values that are at least close enough to the stated value to perform a desired function or achieve a desired result, and/or values that round to the stated value. The stated values include at least the variation to be expected in a typical manufacturing or other process, and may include values that are within 10%, within 5%, within 1%, etc. of a stated value.

In addition, unless otherwise indicated, numbers expressing quantities, constituents, distances, or other measurements used in the specification and claims are to be understood as optionally being modified by the term “about” or its synonyms. When the terms “about,” “approximately,” “substantially,” or the like are used in conjunction with a stated amount, value, or condition, it may be taken to mean an amount, value or condition that deviates by less than 20%, less than 10%, less than 5%, less than 1%, less than 0.1%, or less than 0.01% of the stated amount, value, or condition.

As used herein, the term “between” includes any referenced endpoints. For example, “between 2 and 10” includes both 2 and 10.

Some ranges are disclosed herein. Additional ranges may be defined between any values disclosed herein as being exemplary of a particular parameter. All such ranges are contemplated and within the scope of the present disclosure. Further, recitation of ranges of values herein is intended to serve as a shorthand method of referring individually to each separate value falling within the range. Unless otherwise indicated herein, each individual value is incorporated into the specification as if it were individually recited herein.

The phrase ‘free of’ or similar phrases if used herein means that the composition or article comprises 0% of the stated component, that is, the component has not been intentionally added. However, it will be appreciated that such components may incidentally form thereafter, under some circumstances, or such component may be incidentally present, e.g., as an incidental contaminant.

The phrase ‘substantially free of’ or similar phrases as used herein means that the composition or article preferably comprises 0% of the stated component, although it will be appreciated that very small concentrations may possibly be present, e.g., through incidental formation, contamination, or even by intentional addition. Such components may be present, if at all, in amounts of less than 1%, less than 0.5%, less than 0.25%, less than 0.1%, less than 0.05%, less than 0.01%, less than 0.005%, less than 0.001%, or less than 0.0001%. In some embodiments, the compositions or articles described herein may be free or substantially free from any specific components not mentioned within this specification.

Unless defined otherwise, all technical and scientific terms used herein have the same meaning as commonly understood by one of ordinary skill in the art to which the invention pertains. Although a number of methods and materials similar or equivalent to those described herein can be used in the practice of the present invention, the preferred materials and methods are described herein.

Disclosure of certain features relative to a specific embodiment of the present disclosure should not be construed as limiting application or inclusion of said features to the specific embodiment. Rather, it will be appreciated that other embodiments can also include said features, members, elements, parts, and/or portions without necessarily departing from the scope of the present disclosure. Moreover, unless a feature is described as requiring another feature in combination therewith, any feature herein may be combined with any other feature of a same or different embodiment disclosed herein. Furthermore, various well-known aspects of illustrative systems, methods, apparatus, and the like are not described herein in particular detail in order to avoid obscuring aspects of the example embodiments. Such aspects are, however, also contemplated herein.

### General Overview of Example Embodiments

Disclosed herein are various embodiments and methods related to the utilization of degradable polyimide photopolymers compatible with existing materials, processing, and application requirements of commercial electronics. Specifically, various embodiments of polyimide films comprising degradable ester linkages and robust thioether linkages of varying structure derived from commercially abundant chemical feedstocks are described, as well as methods related to their synthesis, processing, reprocessing, and use in electronic devices.

As described in the background section, recent advances in electronics have led to a widespread accumulation of e-waste. A proposed solution to the problem of e-waste accumulation is the development of reprocessable electronic substrates that allow for simple and cost-effective recycling of electronic components. Widely used e-polymers such as Kapton® possess suitable physical and electronic properties for use in electronics but are difficult to recycle, causing valuable electronic components to be discarded. As a result, developing new polymeric electronic substrates (e-substrates) with built-in reprocessibility via chemical, thermal, or biological means has generated significant research attention, as complete degradation or removal of an e-substrate allows for the collection of expensive and reusable electronic components, minimizing waste and amortizing costs. Typical approaches to developing reprocessable electronic substrates focus on alternative thermoplastic polymers such as polyesters; however, they fall short in thermostability. Specifically, these polymer systems often possess low heat stability well below conventional processing temperatures, and the conditions for hydrolysis can be so innocuous as to occur in ambient environments leading to premature unintended device failure.

Furthermore, traditional thermoplastics are often susceptible to creep and plastic deformation which threaten dimensional stability. Additional shortcomings include that interchain ionic or hydrogen bonds can become active at high frequencies to the detriment of dielectric performance. While other recyclable crosslinked polymers (or “network polymers”) may overcome some drawbacks with thermal and ambient stability, the fabrication and reprocessing of these thermosets is often costly, requiring multi-step processing that involves solvent evaporation to form films.

The degradable photopolymers described herein overcome at least some of the aforementioned shortcomings of traditional e-substrates. Specifically, the degradable photopolymers described herein possess thermal, physical, and electrical properties similar to traditional e-substrates such as Kapton® or similar polyimides, as well as providing built-in degradability, allowing for the reprocessing of both the e-substrates and the electronic components of an electronic device that has reached end-of-life. Furthermore, the photopolymers disclosed herein possess an appropriate molecular design and formulation of photopolymerizable precursors that enables processing of polyimide based materials in the liquid state, which readily enables rapid fabrication of multi-layer packaging of multilayered circuits at near-ambient conditions.

Embodiments described herein may utilize thiol-ene click chemistry as an ideal photopolymerization method for the design of ester-containing networks. Despite free-radical polymerization of acrylate or methacrylate free-radical polymerization being a common choice for photopolymerization, it suffers from oxygen inhibition, often resulting in tacky surfaces due to incompletely reacted monomers. On the contrary, thiol-ene polymerizations have the benefit of little oxygen inhibition and are proven capable of forming thin films with non-tacky, smooth surfaces. These thiol-ene polymerization reactions are activated by light irradiation (e.g., UV), allowing for a simple curing process at relatively low temperatures (e.g., less than about 150° C., less than about 125° C., or less than about 100° C. such as from about 60° C. to about 100° C., from about 70° C. to about 90° C. or about 80° C.) compared to typical polyimide substrates, which often require processing at greater than about 200° C. This low curing temperature allows polyimide substrates to be deposited and cured in the presence of electrical components that may otherwise be damaged by higher temperatures.

Furthermore, embodiments described herein may comprise or be formed from commercially available thiol monomers that possess degradable alkyl ester linkages, such as trimethylolpropane tris 3-mercaptopropionate (TMPMP), Pentaerythritol tetrakis(3-mercaptopropionate) (PETMP), Polycaprolactone tetra(3-mercaptopropionate), Dipentaerythritol Hexakis(3-mercaptopropionate), Tris[2-(3-mercaptopropionyloxy)ethyl] Isocyanurate (TEMPIC), Ethylene Glycol Bis(3-mercaptopropionate) (EBMP), Pentaerythritol tetrakis(3-mercaptobutylate), 1,4-Bis(3-mercaptobutyroyloxy)butane, 1,3,5-Tris[2-(3-mercaptobutanoyloxy)ethyl]-1,3,5-triazine-2,4,6 (1H,3H,5H)-trione, and/or Trimethylol propane tris(3-mercaptobutylate) for example. As a result, depolymerization of these poly(imide-ester) networks via transesterification reactions stimulated at ambient or near ambient temperatures allows successful recovery and reuse of electrical components disposed within polyimide films. Rather than being discarded along with traditional electronic substrates when a device reaches its end-of-life, electronic components disposed within the present degradable polyimide films may be recaptured and reused after the films are degraded.

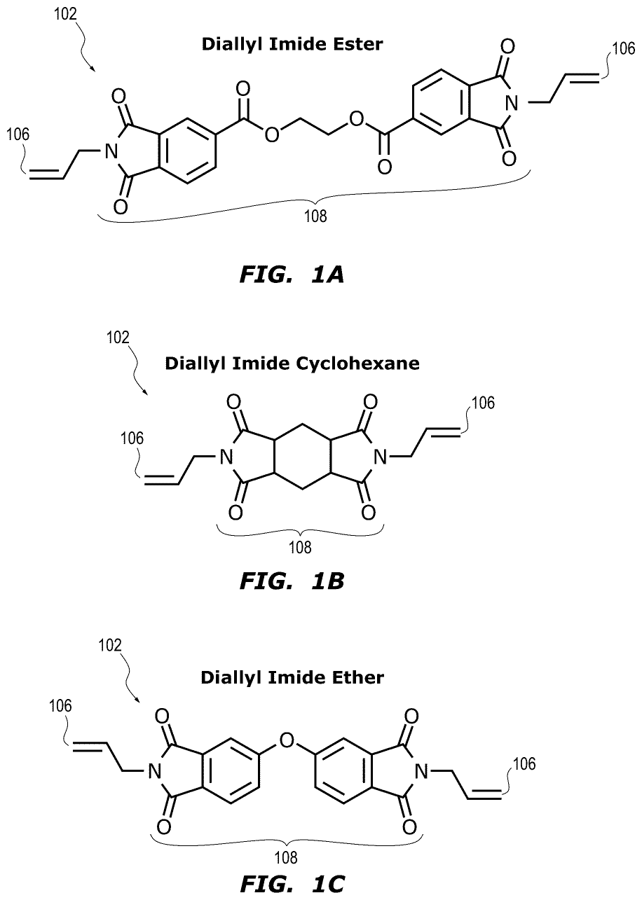

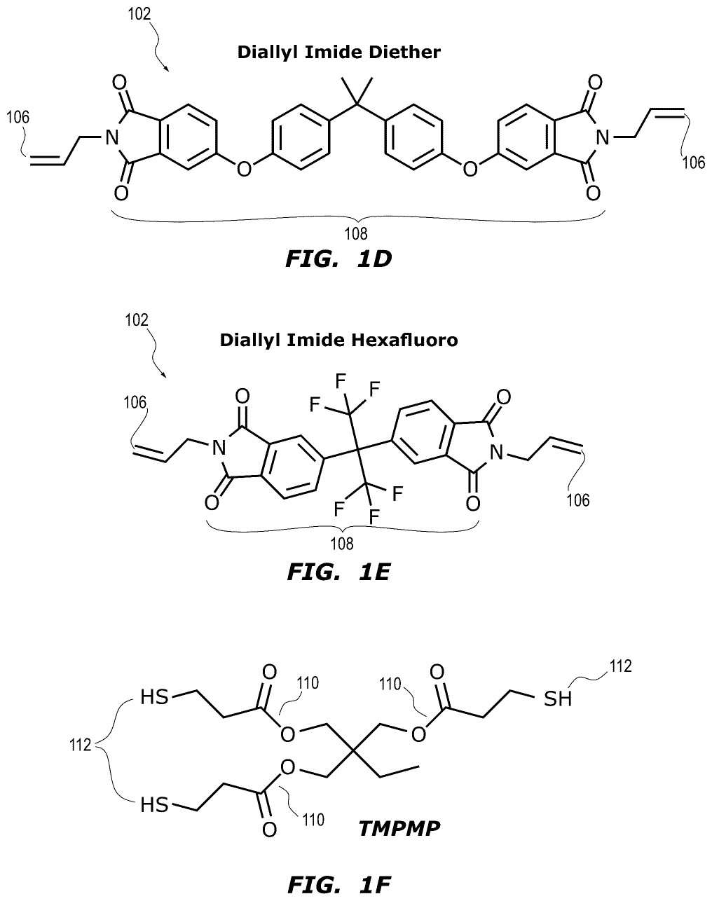

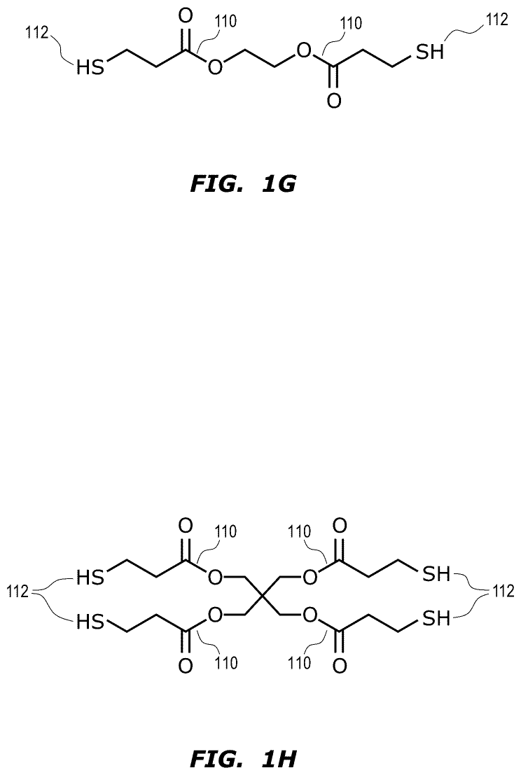

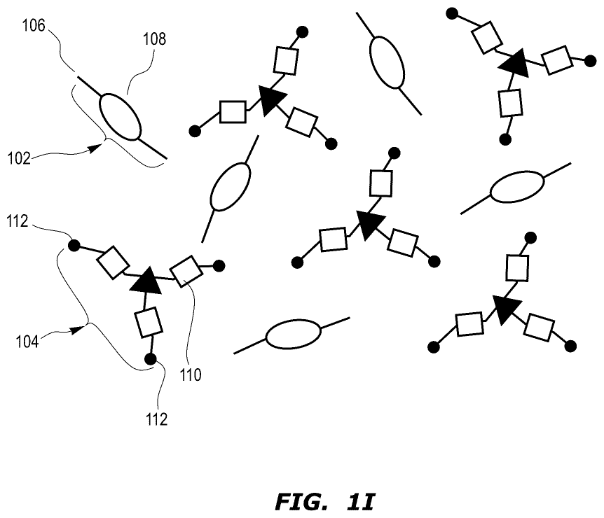

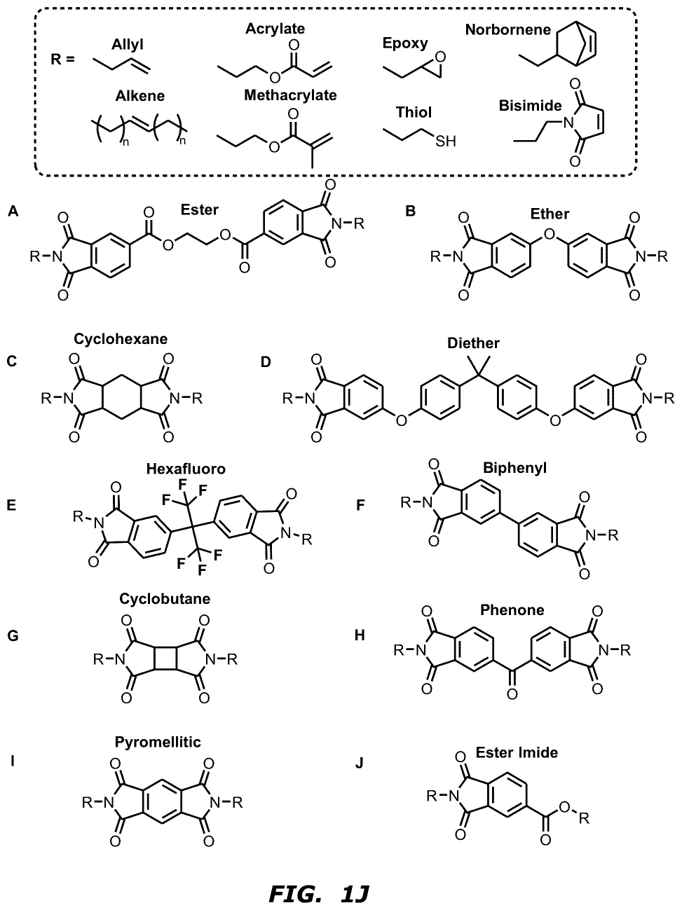

FIGS. 1A-1H illustrate exemplary chemical structures of monomers that can be used to form an exemplary polyimide photopolymer, wherein the monomers comprise various diallyl imide monomers 102 and thiol monomers 104. The diallyl imide monomers 102 may comprise at least one of diallyl imide ester monomers (herein referred to as PI ester) (see FIG. 1A), diallyl imide cyclohexane monomers (herein referred to as PI cyclohexane) (see FIG. 1B), diallyl imide ether monomers (herein referred to as PI ether) (see FIG. 1C), diallyl imide diether monomers (herein referred to as PI diether) (see FIG. 1D), diallyl imide hexafluoro monomers (herein referred to as PI hexafluoro) (see FIG. 1E), and/or others. The diallyl imide monomers 102 illustrated in FIGS. 1A-1E, comprise ene functional groups 106 and a bisimide core 108. The bisimide core accords a resultant polymer substrate the desired physical and electrical properties to be used as an electronics substrate. An exemplary synthesis of the diallyl imide monomers is described and illustrated below. A wide variety of other difunctional imide monomers are also possible, e.g., which may contain reactive groups such as allyl, alkene, acrylate, methacrylate, epoxy, thiol, norbornene, and bisimide. Non-limiting examples of such possible structures are shown in FIG. 1J, which shows exemplary ester (structure A), ether (structure B), cyclohexane (structure C), diether (structure D), hexafluoro (structure E), biphenyl (structure F), cyclobutane (structure G), phenone (structure H), pyromellitic (structure I), and ester imide (structure J). FIG. 1J further shows a variety of possible R groups that may be used within any of the presently described monomers for polymerization, including allyl, alkene, acrylate, methacrylate, epoxy, thiol, norbornene, and bisimide. While 2 R groups are shown in the various illustrated structures, it will be appreciated that each R group may be independently selected relative to one another.

The thiol monomers 104 may comprise a thiol monomer with degradable ester linkages 110, examples of which include, but are not limited to trimethylolpropane tris 3-mercaptopropionate, herein referred to as TMPMP (see FIG. 1F), ethylene glycol di(3-mercaptopropionate), herein referred to as GDMP (see FIG. 1G), pentaerythritol tetra(3-mercaptopropionate), herein referred to as PETMP (see FIG. 1H). Combinations of such or other thiol monomers may also be used. Furthermore, the thiol monomers 104 may comprise two or more, or 3 or more thiol functional groups 112. The thiol functional groups 112 can react with the ene functional groups 106, forming a thioether linkage between the diallyl imide monomers 102 to the thiol monomers 104, wherein the thiol-ene conversion reaction (i.e., polymerization reaction) is initiated by a free radical photoinitiator and light irradiation. When the diallyl imide monomers 102 and the thiol monomers 104 are mixed in a vial or other container and melted at about 80° C., they form a stable liquid resin (see FIG. 1I). Because the polymerization reaction is initiated by a free radical photoinitiator and light irradiation (e.g., UV), the liquid resin remains unreacted until a curing process is initiated. This allows for the novel and advantageous manufacturing techniques described below.

While diallyl imide monomers may be principally described, it will be appreciated that a wide variety of difunctional monomers based on the structures shown in FIG. 1J can also or alternatively be used.

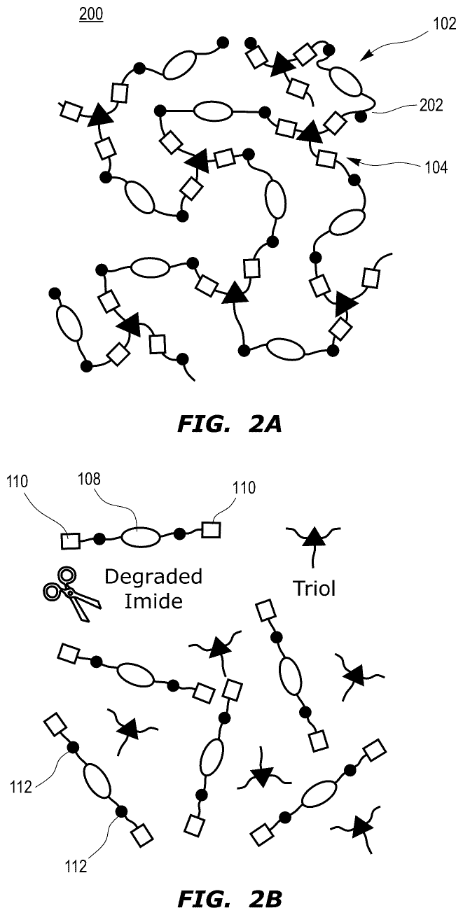

FIG. 2A illustrates a schematic of a polymer network 200 formed from the diallyl imide monomers 102 and the thiol monomers 104. In the example illustrated in FIG. 2A, TMPMP may be used as the thiol monomer 104. The diallyl imide monomers 102 can be reacted with excess thiol monomers 104 to form the polymer network 200. Because TMPMP comprises three thiol groups, and can thus bond with 3 diallyl monomers, the resulting polymer network 200 displays significant cross linking. The degradable ester linkages 112 allow for simple degradation of the polymer network 200 under mild conditions. For example, the degradable ester linkages 112 may be degraded with a transesterification reaction at or near ambient temperature (i.e., at room temperature). FIG. 2B illustrates polymer network 200 after degradation.

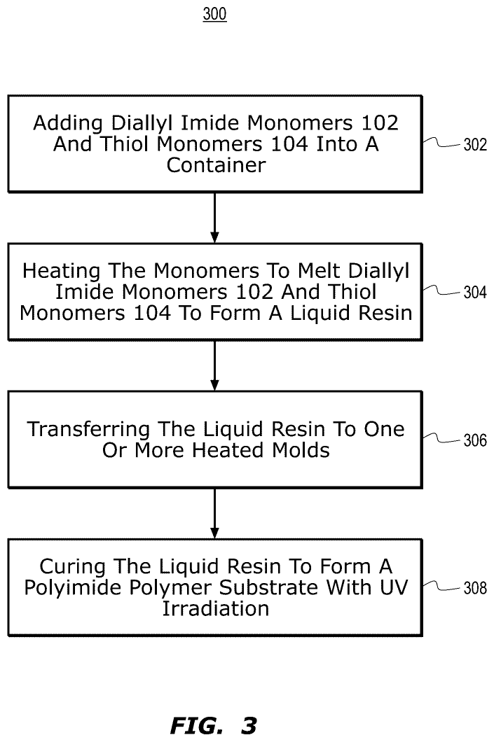

FIG. 3 illustrates method 300, wherein method 300 is used to synthesize and cure an exemplary polyimide photopolymer, wherein method 300 comprises steps 302, 304, 306 and 308. Step 302 involves adding diallyl imide monomers 102 and thiol monomers 104 into a vial or other container. Step 304 involves heating the monomers to melt diallyl imide monomers 102 and thiol monomers 104 to form a liquid resin (e.g, a mixed composition of such monomers). Step 306 involves transferring the liquid resin to one or more heated molds. The liquid resin formed in step 304 possesses a sufficient pot life (order of minutes or greater) such that transfer into heated molds does not result in any significant phase separation or solidification. The mold may be heated to a desired temperature, such as about 80° C. This allows for simplified processing techniques compared to other polymers used as e-substrates. Step 308 involves curing the liquid resin to form a polyimide substrate, e.g., using UV irradiation. In one example, the liquid resin is irradiated at 405 nm (5 mW/cm²) at about 80° C. for about 10 minutes to polymerize the resin. More generally, the polymerizing irradiation may be from about 350 nm to about 450 nm, or from about 380 nm to about 430 nm, or from about 390 nm to about 415 nm. The intensity may be from about 1 mW/cm² to about 10 mW/cm², or from about 2 mW/cm² to about 8 mW/cm² or from about 3 mW/cm² to about 6 mW/cm². Curing time may range from about 1 minute to about 30 minutes, from about 3 minutes to about 20 minutes, or from about 5 minutes to about 15 minutes. Curing temperature may be less than about 150° C., less than about 125° C., or less than about 100° C. such as from about 60° C. to about 100° C., from about 70° C. to about 90° C. or about 80° C.

Fourier-transform infrared (FTIR) spectroscopy confirmed complete disappearance of the thiol peak (2569 cm⁻¹) and nearly complete disappearance of the alkene peak (3092 cm⁻¹) after UV irradiation. Monitoring the thiol peak by real-time FTIR confirms the rapid polymerization kinetics typical in neat thiol-ene photopolymerization systems, e.g., achieving 63% thiol conversion within 10 seconds with 5 mW/cm² light intensity. The resulting materials were found to be free-standing, glassy, tough, and transparent films, allowing for the films to be readily handled and flexed at −200 μm film thickness. More generally, film thickness may be from about 10 μm to about 5000 μm, from about 25 μm to about 3000 μm, from about 50 μm to about 1000 μm, or from about 50 μm to about 500 μm.

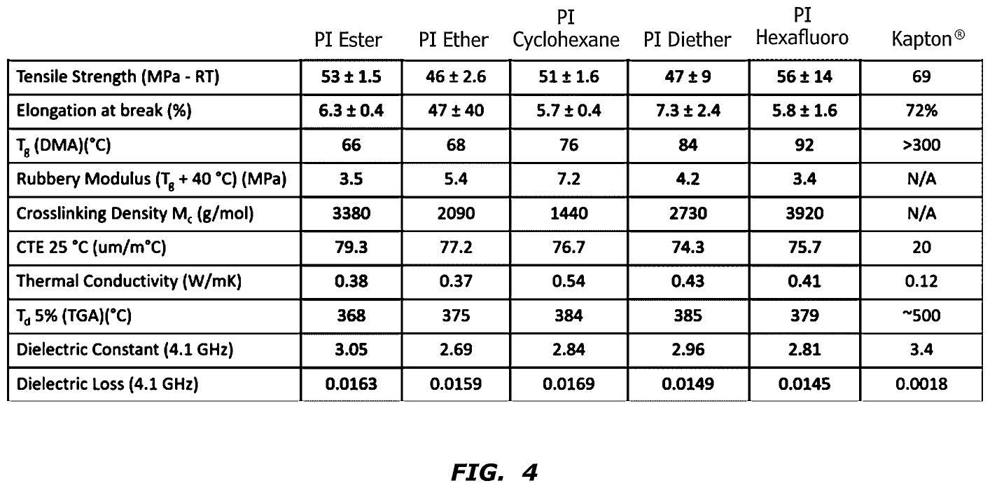

The material properties of the cured polymers were examined, including the glass transition temperature T_{g} by (dynamic mechanical analyzer (DMA)), tensile strength, elongation at break, rubbery modulus, crosslinking density Mc, coefficient of thermal expansion (CTE), and thermal stability T_{d} (by thermogravimetric analysis (TGA)), thermal conductivity, the dielectric constant, and dielectric loss. The material properties for polyimides formed from PI ester, PI ether, PI cyclohexane, PI diether, and PI hexafluoro monomers are listed in FIG. 4, as well as the material properties of Kapton® (for purposes of comparison).

Varying the diallyl imide monomer used to form a polyimide substrate results in polymer substrates with a range of T_{g} values from 66° C. to 92° C. (see FIG. 4). More generally, desired glass transition temperatures may range from about 50° C. to about 150° C., or from about 60° C. to about 100° C. Notably, polymers comprising PI hexafluoro and PI diether (diallyl imide monomers containing rigid linkages, such as a quaternary carbon) resulted in the highest T_{g} values while polymers comprising PI ester and PI ether (diallyl imide monomers containing flexible linkages) had the lowest T_{g} values. Observing such a structure-property relationship in these networks confirms a high fidelity between the polymer design, synthesis, and processing. These properties are significantly lower than Kapton®, allowing for straightforward resin casting and photopolymerization on the scale of minutes at lower temperatures. On the other hand, Kapton® requires high heat (200° C. to 300° C.) to undergo imidization over the course of hours, which requires a higher energy input as compared to that required to perform photopolymerization of the polyimide substrates disclosed herein.

Using DMA, PI-cyclohexane is shown to possess the highest rubbery modulus (7.2 MPa) which suggests an average molecular weight between crosslinks (Mc) of 1440 g mol⁻¹, which is in alignment with PI cyclohexane possessing the lowest molar mass of the tested diallyl imide monomers. On the other hand, PI-hexafluoro is shown to possess the lowest rubbery modulus (3.4 MPa) and the highest Mc (3920 g mol⁻¹), in agreement with PI-hexafluro possessing the highest molar mass of the tested diallyl imide monomers.

The thermal properties of the cured degradable polyimide substrates were similar to conventional polyimides, possessing high thermal stability, with temperatures for 5% weight degradation ranging from 368° C. to 385° C. (see FIG. 4), far above conventional solder reflow temperatures (265° C.). The cured degradable polyimide substrates described herein also exhibit thermal conductivity ranging from 0.38 to 0.54 Wm⁻¹K⁻¹, which is significantly higher than that of Kapton HN® (0.12 W m⁻¹K⁻¹). More generally, thermal conductivity may range from about 0.2 Wm⁻¹K⁻¹ to about 1 Wm⁻¹K⁻¹, from about 0.3 Wm⁻¹K⁻¹ to about 0.8 Wm⁻¹K⁻¹, or from about 0.35 Wm⁻¹K⁻¹ to about 0.6 Wm⁻¹K⁻¹. Relatively higher thermal conductivity is often desirable in e-substrates for purposes of heat dissipation. In fact, the cured photopolymers described herein possess thermal conductivities similar to Kapton MT®, a commercial polyimide which contains additives specifically configured to improve its thermal conductivity (0.46 Wm⁻¹ K⁻¹). No such additives are required with the presently described embodiments. Together, these thermal properties compare well with commercial polyimides and even outperform them in some instances.

Of primary concern for dense electronic circuits is the dielectric behaviour of the underlying e-substrate. Accordingly, the dielectric properties of the disclosed polymers were measured, including the dielectric constant and dielectric loss (FIG. 4) of the disclosed polyimide network polymers at ultra-high frequency regimes relevant to wireless data transfer (Cellular networks, WiFi, Bluetooth, Ultra-wide Band, etc.). At 4.1 GHz, these photopolymers possess dielectric constants (Dₖ) ranging from 2.69 (PI-ether) to 3.05 (PI-ester), slightly lower but still comparable than that of Kapton-NH (3.4). The relatively high dielectric strength of the PI-ester polymer originates from the polar ester groups and could be further accentuated by high dielectric fillers. Dielectric loss (D_{f}) values were found to range from 0.0145 to 0.0169, which is again comparable to commercially available polyimides with dielectric loss values ranging from 0.0037 to 0.020. More generally, dielectric constant at 4.1 GHz may range from about 2 to about 5 or from about 2.5 to about 4, or from about 2.7 to about 3.5. The disclosed polymers therefore possess similar dielectric behaviour to traditional e-substrates such as Kapton®, confirming the molecular design motif and suggesting suitability in many applications.

The measured Young's moduli range of cured degradable polyimide substrates ranges from 1180 MPa to 1330 MPa, with the ultimate tensile strength ranging from 46 MPa to 56 MPa (see FIG. 4). More generally, Young's modulus may range from about 800 to about 1800 MPa or from about 900 MPa to about 1600 MPa, from about 1000 MPa to about 1500 MPa or from about to about 1100 MPa to about 1400 MPa. Ultimate tensile strength may be at least about 30 mPa, at least about 35 MPa, at least about 40 MPa, at least about 45 MPa, no more than about 100 MPa, no more than about 80 MPa, or no more than about 75 MPa. The polymers exhibit moderate extensibility, with elongation-at-break values of about 6%, except for PI-ether with an elongation-at-break of 47%, likely due to its flexible ether linkage providing additional backbone mobility. While these physical properties are lower than commercially used polyimides, typical commercially available polyimides undergo rigorous process optimization and have additives to give them their robust toughness. The polyimides described herein may be modified through similar process optimization to improve toughness. For example, elongation at break may be at least 5%, at least 10%, at least 20%, at least 30%, at least 40%, such as from 5% to 200%, from 5% to 150%, from 5% to 100%, from 20% to 80%, or various other values, through optimization. The results indicate that all five tested thiol-ene poly(imide ester) networks are mechanically robust and capable of serving as e-substrates.

The dimensional stability of the degradable polyimide substrates described herein was also evaluated. Creep tests conducted on PI ester showed very little strain using film samples in tension, performed at 25° C., 100° C., and 200° C. with 0.1 MPa of constant stress. At ambient temperature of 25° C., a low creep strain of 0.2% after 50 minutes was observed while at 200° C. a creep strain of 5% was found showing the polymers described herein possess high temperature creep resistance.

The use of commercially available polyimide films as e-substrates relies predominantly on pre-fabricated polyimide films due to the inability to process polyimide films in a liquid state while staying within the acceptable thermal window for many electronic subcomponents. In other words, commercially polyimide films have to be processed (i.e. cured) before electrical components can be added thereto due to the high heat required to cure conventional polyimide films. For example, linear, aromatic PI films have a prohibitively high melting temperature (Tₘ>300° C.) that prevents processing these films in a liquid state in the presence of electrical components, and alternatives based on liquid poly(amic acids) precursors still require imidization steps at >250° C. to initiate ring-closing reactions.

In order to obtain dense electronic circuits with conventional, (i.e., prefabricated PI film) approaches, one would need to build each electronic layer onto a film separately and then align and stack the films. Particularly challenging is obtaining the necessary through-layer electronic connections. This requirement usually entails additional subtractive steps to drill through the substrate to create a “via” and then applying suitable solder to achieve electrical conduction. Electronic components placed on top of the films break 2D planarity and different components are often at different heights. Applied liquid “build-up layers” can conceivably accommodate this height differential, but adhesion is not trivial. Adhesives also add to thickness and create discrete transitions in stiffness and other problems, which configurations consume valuable real estate while also threatening overall flexibility and mechanical reliability.

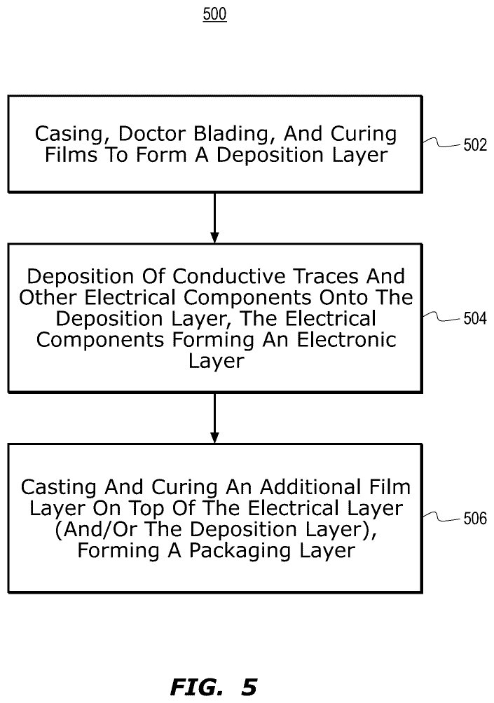

By contrast, the PI films disclosed herein are viscous liquids at modest processing temperatures before curing, which permits straightforward deposition, casting, and levelling of thin layers iteratively. FIG. 5 illustrates a method 500 that may be used to manufacture circuits with the degradable polyimide substrates disclosed herein. Method 500 comprises steps 502, 504, and 506. Step 502 involves casing, doctor blading, and curing films to form a deposition layer. The deposition layer may be as thin as 100 microns or perhaps even less and may comprise the degradable polyimide substrates described herein. Furthermore, the deposition layer films may be preformed, wherein the deposition layer films comprise a shape suitable for deposition of electrical components thereto. The deposition layer may be cured using a method such as that illustrated in FIG. 3. Step 504 involves deposition of conductive traces and/or other electrical components onto the deposition layer, the electrical components forming an electronic layer. The thermal resistance of the degradable polyimide films (i.e., the deposition layer film) permits solder reflow of Pb-free solder at temperatures of 265° C. for 10 min. Step 506 involves casting and curing an additional film layer on top of the electrical layer (and/or the deposition layer), forming a packaging layer. The packaging layer planarizes, insulates and protects the electronic layer. The packaging layer may be cured in the presence of deposited electrical components in the electronic layer. Steps 502-506 may be repeated to form multilayered circuits.

In some instances, such as when method 500 is used to manufacture multilayered circuits, layers or portion of such layers comprising the degradable polyimide substrates disclosed herein (i.e., the deposition layer and/or the packaging layer) may be selectively cured, allowing for the formation of “vias” or gaps in the degradable polyimide films. Rather than insulating the entire circuit, these selectively cured layers, herein referred to as redistribution layers (RDLs), can include vias in the insulating layer, selectively insulating certain regions of the electrical components and leaving others (i.e., those flanking the vias) uninsulated. By employing photomasks, an RDL can be selectively photopolymerized (i.e. UV cured) in desired regions and leave unexposed regions uncured. This additive approach yields the necessary vias directly. The uncured resin can be removed, resulting in an RDL comprising a via. The via may then be backfilled with a conductor, which electrically connects circuits embedded in adjacent layers in a multilayered circuit. Accordingly, another layer of electrical components can then be built on top of the first layer while simultaneously achieving the desired insulation and conductivity with the previous layer. This workflow can be integrated into method 500 and is repeatable and infinite for an arbitrary number of layers of flexible circuitry, significantly reducing the complexity of building multilayered polyimide based circuits.

An ohmmeter probe was used to measure the conductivity of the electrical components before and after deposition of an exemplary packaging layer according to step 504 of method 500. Placing an ohmmeter probe on the bare conductive trace of the layer measured R=0.8Ω but after deposition and curing of the buildup layer, the probe measured an open circuit (R>10⁸Ω). These results indicate that the degradable polyimide substrates disclosed herein are a suitable insulator for use as an e-substrate.

As discussed above, the polymers described herein are degradable after use in an electronic circuit. Because the cost of electrical components is usually higher than that of the polymer substrate, recapturing electrical components under mild conditions to permit reuse is attractive. The degradable polyimide substrates described herein may be degraded using a depolymerization reaction under mild conditions (i.e., ambient temperature). The depolymerization reaction may promote transesterification reactions that target the degradable ester linkages in the PI photopolymer network. For example, one mild transesterification reaction may involve stimulating the transesterification reaction with a methanol solution comprising potassium carbonate (K₂CO₃) as the catalyst. Other solutions, including other alcohols or other components may also be suitable. Similarly, other salts, metals, or organic bases, e.g., other alkali metal carbonates, alkali hydroxides, or organic bases may also be suitable such as sodium carbonate, strontium carbonate, lithium carbonate, potassium hydroxide, sodium hydroxide, triethylamine (TEA), triazabicyclodecene (TBD), tetramethylguanidine, 1,8-diazabicyclo(5.4.0)undec-7-ene (DBU), zinc (II) acetylacetonate, and/or zinc acetate.

In some instances, to improve mass transport during the reaction, about 50% by volume dichloromethane (DCM) may be added into the methanol solution. The addition of DCM drastically increases the rate of depolymerization. Complete disappearance of the network polymer occurs within 24 hours at ambient conditions for polymers with the same sample dimensions. Other solvents that may be used include, but are not limited to ethanol, 2-proponal, 1-proponal, acetonitrile, chloroform, tetrahydrofuran, acetone, and/or ethyl acetate.

The depolymerization kinetics of multiple embodiments of polyimide substrates were measured by weighing the residual mass of the polymer sample at varied durations. The PI-ester depolymerized the fastest, completing within 12 hours. Importantly, PI-ester samples showed little swelling, suggesting that the depolymerization reaction rate exceeded the rate of diffusion. Initially, the other four PI networks showed significant swelling—gaining mass during the first few hours as the solution infiltrates the network—prior to sufficient transesterification disrupting network percolation resulting in the macroscopic films breaking apart. Chemical analysis using ¹H-NMR of the resulting small molecules confirms the formation of methyl esters at 3.76 ppm shifting from the original mercaptopropionate peak at 4.03 ppm. The aromatic ester adjacent proton peaks also shift from the ester monomer at 4.75 ppm to the degraded monomer's methyl ester location at 3.79 ppm. Thus, ¹H-NMR confirms that transesterification with methanol is successful in depolymerizing the polyimide networks under ambient conditions. Recovery of electronic components embedded in the polymers was also demonstrated, wherein degradation of the polymer layers did not damage the electrical components, allowing for recovery of such precious metals and the like.

Additional embodiments of a degradable polyimide substrate may utilize epoxy monomers 602 in addition to the diallyl imide monomers 102 and the thiol monomers 104, wherein the addition of epoxy monomers 602 into the starting liquid resin results in a multimodulus polymer. The multimodulus polymer can be cured to yield a diverse range of polymers from soft elastomers (Esoft˜400 kPa, dL/L0˜300%) to glassy thermosets (Estiff˜1.6 GPa, dL/L0˜3%) depending on the extent to which the polymer is cured with UV light. Specifically, these embodiments utilize photoinitiated thiol-ene reactions followed by thiol-epoxy step-growth polymerization and then epoxy homopolymerization at elevated temperatures. This precursor design creates a reactive sequence whereby the photoirradiation dosage during processing determines the thiol and ene functional group conversion in a first stage, which determines the amount of “soft” thiol-epoxy network created in the second stage, which consequently determines the amount of “stiff” epoxy network formed in the third stage. Thus, the applied photodosage directly dictates the extent of “soft” and “stiff” segments within the polymer film. These sequential reactions result in the full consumption of readily reacted groups during processing, which imparts environmental stability to the cured polymer film.

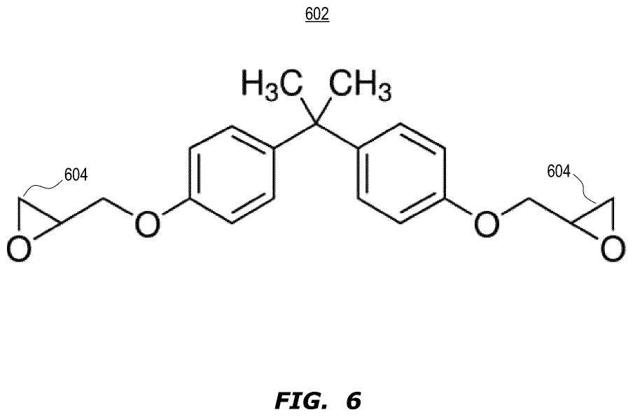

FIG. 6 illustrates an example of an epoxy monomer 602, wherein diallyl imide monomers 102, thiol monomers 104, and epoxy monomers 602 can be provided in a 1:1:1 or other desired ratio and may be cured to form a multimodulus polymer. In some embodiments, the epoxy monomer 602 comprises bisphenol A diglycidyl ether (BisDE) and/or others. Epoxy monomer 602 comprises two or more epoxy groups 604 that can polymerize with thiol groups 110 forming thiol-epoxy linkages, or which can polymerize with other epoxy groups 604 forming epoxy-epoxy linkages.

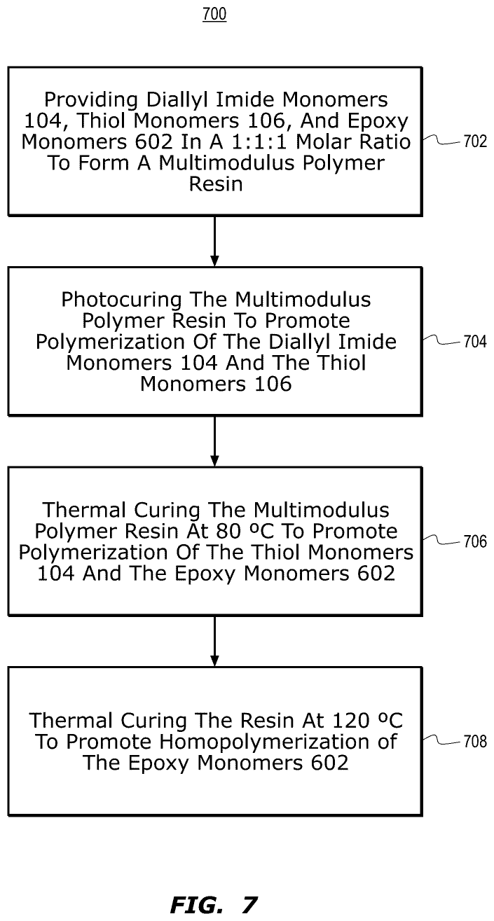

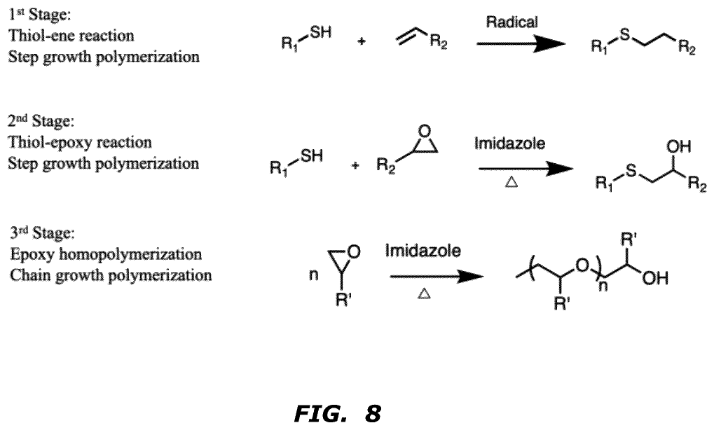

FIG. 7 illustrates a method 700 for selectively curing the multimodulus polymer described hereinabove. Step 702 involves providing diallyl imide monomers 104, thiol monomers 106, and epoxy monomers 602, e.g., in about a 1:1:1 molar ratio, to form a multimodulus polymer resin. Step 704 involves photocuring the multimodulus polymer resin to promote polymerization of the diallyl imide monomers 104 and the thiol monomers 106. Because the thiol-ene polymerization reaction is photoinitiated while the thiol-epoxy polymerization and epoxy homopolymerization reactions are not, only the thiol-ene polymerization reaction occurs during step 704. Step 706 involves thermal curing the multimodulous polymer resin (e.g., at about 80° C. or other similar temperature ranges described herein) to promote polymerization of the thiol monomers 104 and the epoxy monomers 602. Step 708 involves thermal curing the resin at a higher temperature (e.g., at about 120° C.) to promote homopolymerization of the epoxy monomers 602. FIG. 8 illustrates the chemical reactions that occur during step 704 (first stage), 706 (second stage), and 708 (third stage). In an embodiment, the first thermal curing step may occur at from about 60° C. to about 100° C., or from about 70° C. to about 90° C., while the second thermal curing step may occur at from about 100° C. to about 140° C., or from about 110° C. to about 130° C.

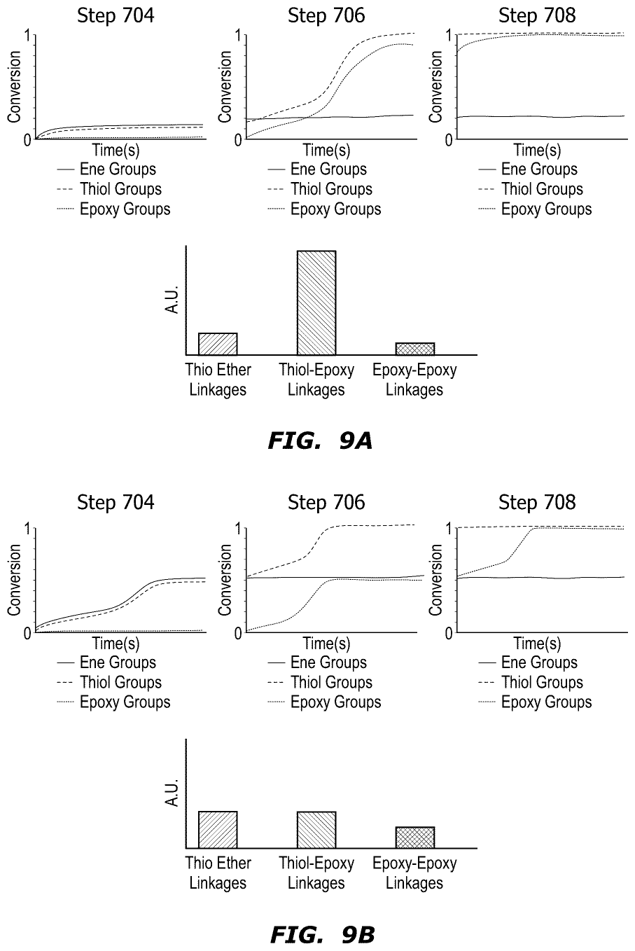

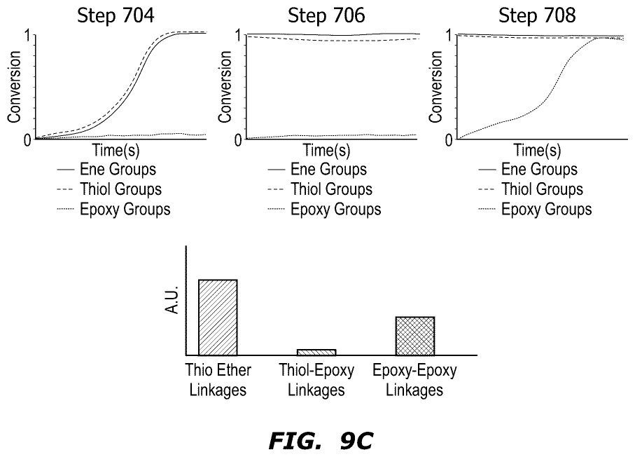

Varying the photodosage in step 704 affects the extent to which the diallyl imide monomers 102 and the thiol monomers 104 polymerize. This effect is illustrated in FIGS. 9A-9C. For example, when a low photodosage (e.g., 0 to about 40 mJ/cm²) is applied to the multimodulus polymer resin in step 704, little to no polymerization between the diallyl imide monomers 102 and the thiol monomers 104 occurred (see FIG. 9A). In such an embodiment, little to no thiol-ene polymerization occurs during step 704, enabling most or all of the thiol groups on the thiol monomers 104 to be available for thiol-epoxy conversion during step 706, wherein the thiol groups undergo nucleophilic addition to the epoxide groups on the epoxy monomers 602. Consequently, after step 706, only a small amount of the epoxide groups on the epoxy monomers 602 are available to undergo homopolymerization in step 708. The resulting polymer substrate therefore contains a relatively high proportion of thiol-epoxy linkages and a relatively low proportion of epoxy-epoxy linkages. Because the thiol-epoxy polymer network forms a soft and stretchable material and the epoxy homopolymer network forms a firm and stiff material, by maximizing the amount of thiol-epoxy polymerization by curing with a low photodosage during step 704, a soft (E˜410 kPa), stretchable material with 300% elongation (dL/L₀) is produced.

As illustrated in FIG. 9B, when a moderate photodosage (e.g., about 40 to about 120 mJ/cm²) is applied to the multimodulus polymer resin in step 704, the photopolymerization consumes thiol groups and ene groups evenly, wherein the residual thiol groups serve as a limiting reagent and consume equimolar epoxy groups of the epoxy monomers 602 in the step 706. The remaining available epoxy groups undergo homopolymerization in step 708. The resulting polymer substrate contains a lower proportion of thiol-epoxy linkages and a higher proportion of epoxy-epoxy linkages compared to an embodiment that uses a lower photodosage (e.g., 0 to about 40 mJ/cm²) during step 704.

As illustrated in FIG. 9C, when a high photodosage (e.g., about 120 to about 175 mJ/cm²) to the multimodulus polymer resin in step 704, most or all of the diallyl imide monomers 102 and the thiol monomers 104 polymerize to form thioether linkages. With a low proportion of unreacted thiol-groups remaining after step 704, the thiol-epoxy addition is minimal during step 706, and nearly all of the epoxide monomers 602 homopolymerize during step 708. In such an embodiment, by minimizing the amount of thiol-epoxy polymer network and maximizing the amount of epoxy-epoxy polymer network after step 708, the resulting multimodulus polymer is firm and stiff.

### Example Procedures

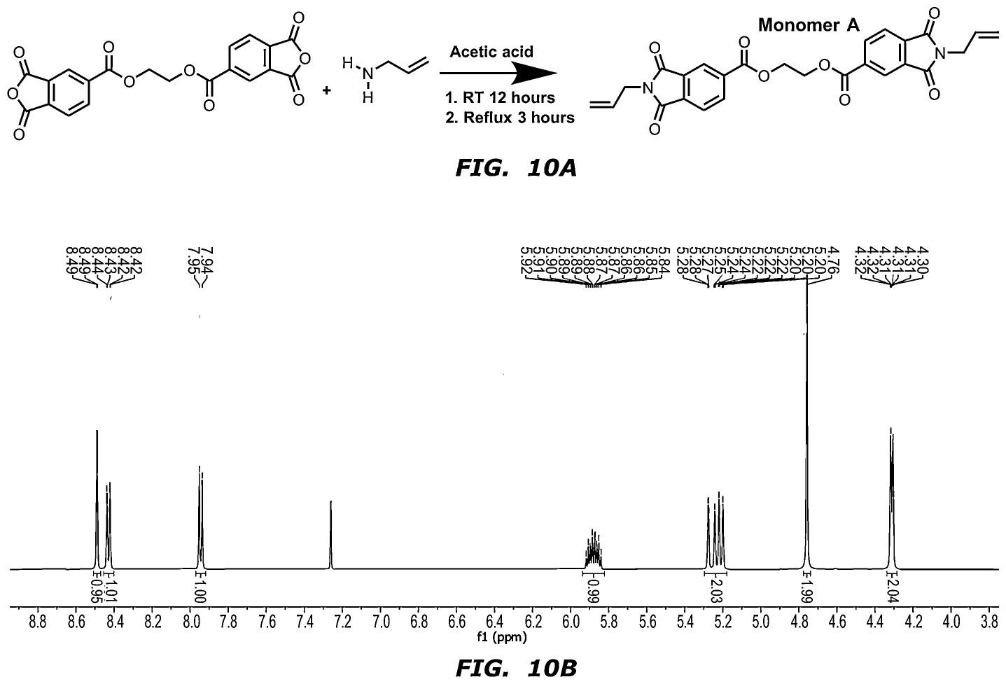

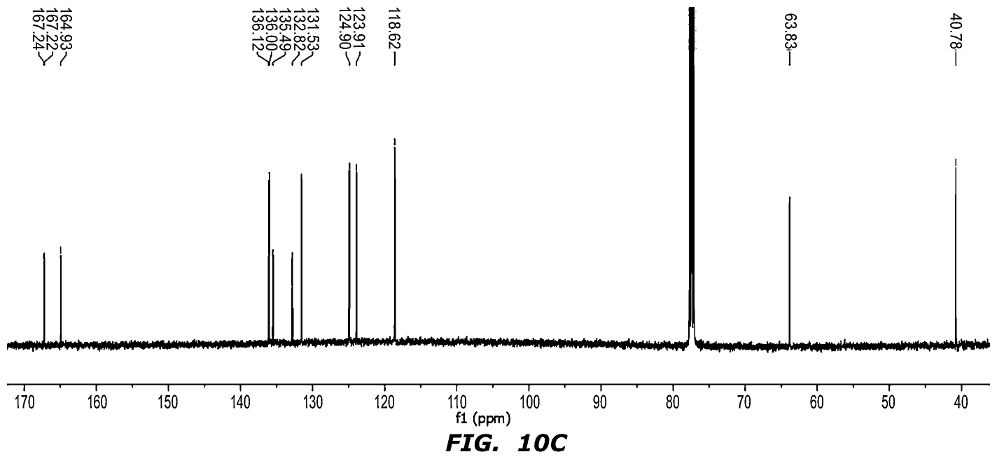

FIG. 10A is schematically illustrates an example synthesis used to produce PI ester. In a 1 L round bottom flask 20 grams (48.7 mmol) of ethane-1,2-diyl bis(1,3-dioxo-1,3-dihydroisobenzofuran-5-carboxylate) was suspended in 250 mL of acetic acid. The mixture was stirred while 7.3 mL (97.5 mmol) of allyl amine was added dropwise to the solution. The flask was stirred for 12 hours with mixture becoming clear. The mixture was then refluxed for 3 hours with any remaining solids dissolved. The flask was then cooled to room temperature and 250 mL of DI water added. The flask was again warmed to reflux or until solids were dissolved. Once the flask was cooled back to room temperature solids were filtered, rinsed with DI water. Solids were recrystallized with 250 mL of acetone and dried under vacuum at 80° C. for 12 hours to give an off-white powder (20.0 g). Yield: 84%. Melting Point (M.P.): 112° C. The product was analyzed with Fourier transform infrared (FTIR), ¹H-NMR, and ¹³C-NMR. FTIR (ATR): ν=3078, 2982, 2914 (C—H), 1778, 1722, 1700 (C═O), 1626 (C═C), 1480, 1423, 1393, 1335, 1271 cm⁻¹. ¹H-NMR (500 MHz, CDCl₃) δ 8.49 (s, 2H), 8.43 (d, J=7.7 Hz, 2H), 7.94 (d, J=7.7 Hz, 2H), 5.88 (m, 2H), 5.30-5.18 (m, 4H), 4.76 (s, 4H), 4.31 (d, J=5.8 Hz, 4H). ¹³C NMR (126 MHz, CDCl₃) δ 166.99, 164.68, 135.89, 135.75, 135.25, 132.58, 131.28, 124.66, 123.67, 118.38, 63.59, 40.54. FTIR, ¹H-NMR, and ¹³C-NMR confirm successful synthesis of PI ester, as shown in FIGS. 10B-10c.

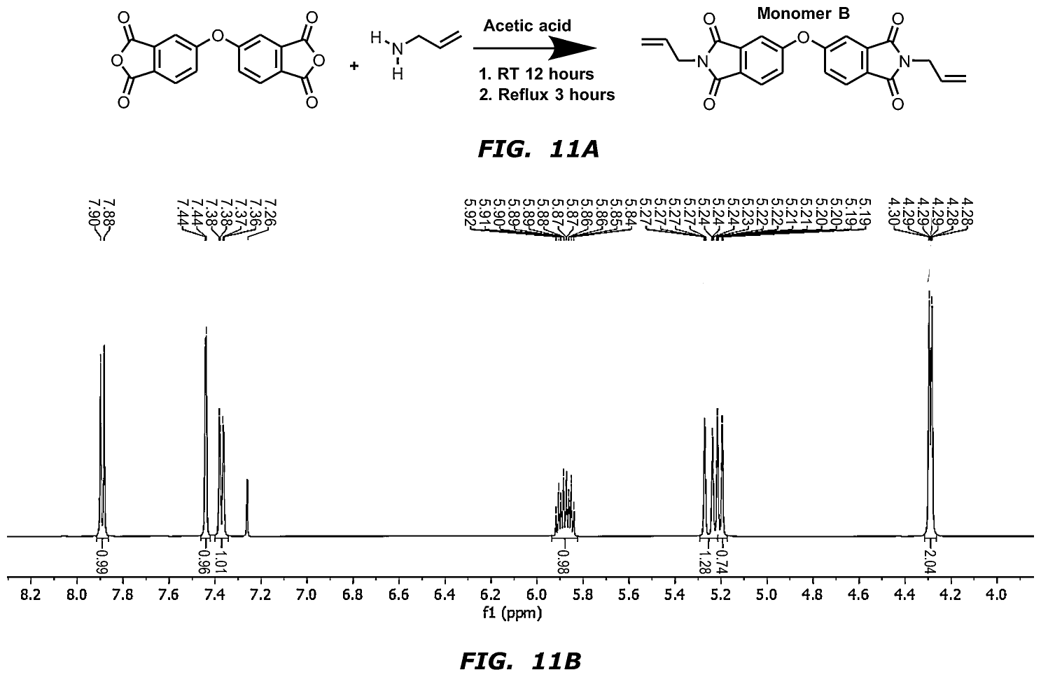

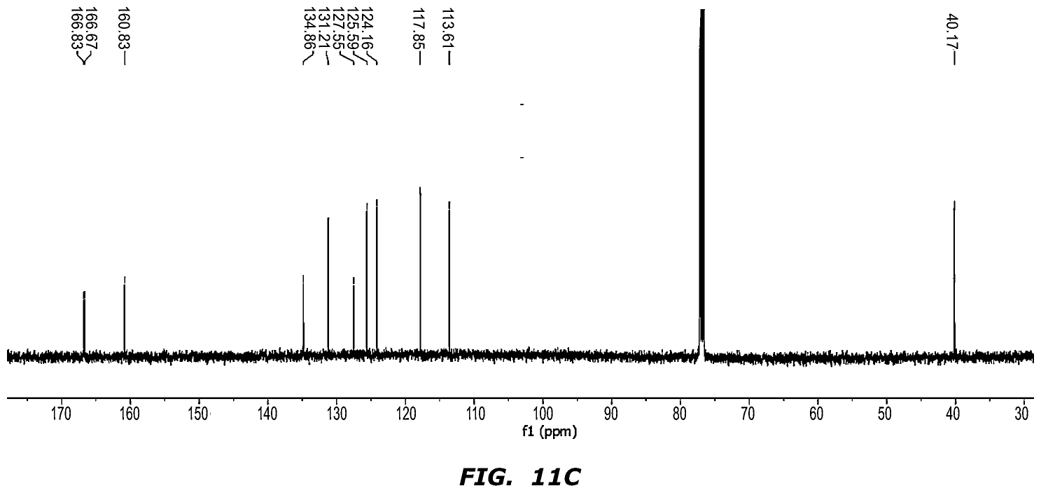

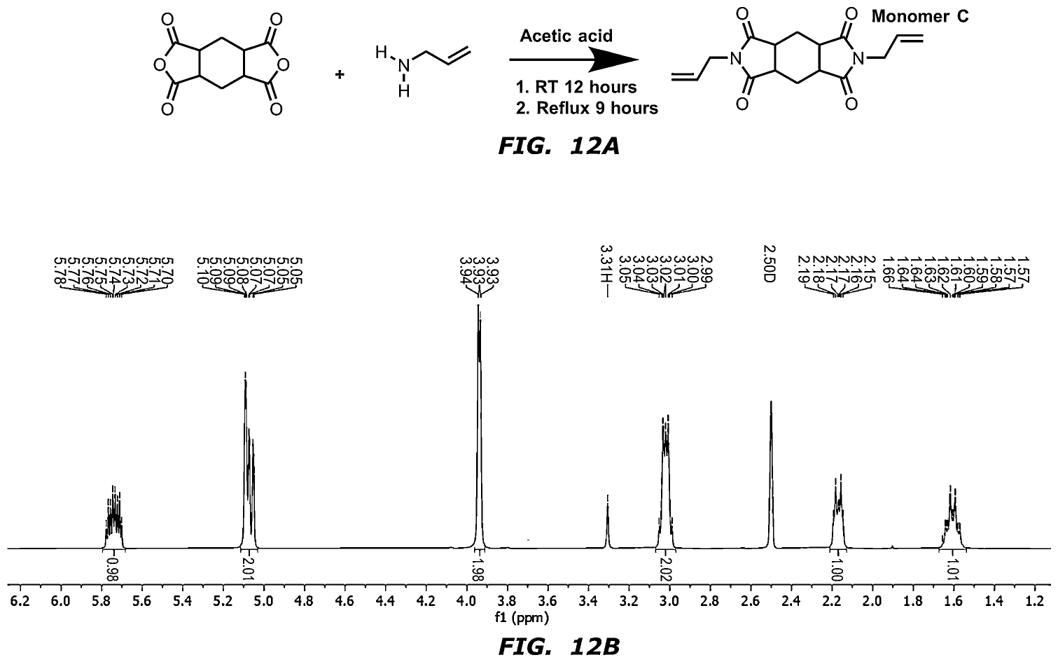

FIG. 11A schematically illustrates an example synthesis used to produce PI ether. In a 1 L round bottom flask 20 grams (64.5 mmol) of 4,4′-Oxydiphthalic anhydride was suspended in 250 mL of acetic acid. The mixture was stirred while 9.65 mL (129 mmol) of allyl amine was added dropwise to the solution. The flask was stirred for 12 hours with mixture becoming clear. The mixture was then refluxed for 3 hours with any remaining solids dissolved. The flask was then cooled to room temperature and 250 mL of DI water added. The flask was again warmed to reflux or until solids were dissolved. Once the flask was cooled back to room temperature solids were filtered, rinsed with DI water. Solid was recrystallized in 150 mL of acetone and dried under vacuum at 80° C. for 12 hours to give a white powder (19.8 g). Yield: 91%. M.P. 150° C. The product was analyzed with Fourier transform infrared (FTIR), ¹H-NMR, and ¹³C-NMR. FTIR (ATR): ν=3079, 3031, 2987, 2924 (C—H), 1768, 1700, (C═O), 1605 (C═C), 1475, 1422, 1384, 1360, 1270 cm⁻¹. ¹H NMR (500 MHz, CDCl₃): δ 7.89 (d, J=8.1 Hz, 2H), 7.44 (s, 2H), 7.37 (d, J=8.2 Hz, 2H), 5.88 (m, 2H), 5.25-5.20 (m, 4H), 4.29 (d, J=5.6 Hz, 4H). ¹³C NMR (126 MHz, CDCl₃): δ 167.34, 167.18, 161.34, 135.37, 131.72, 128.06, 126.10, 124.67, 118.36, 114.12, 40.67. FTIR, ¹H-NMR, and ¹³C-NMR confirm successful synthesis of PI ether as shown in FIGS. 11B-11C.

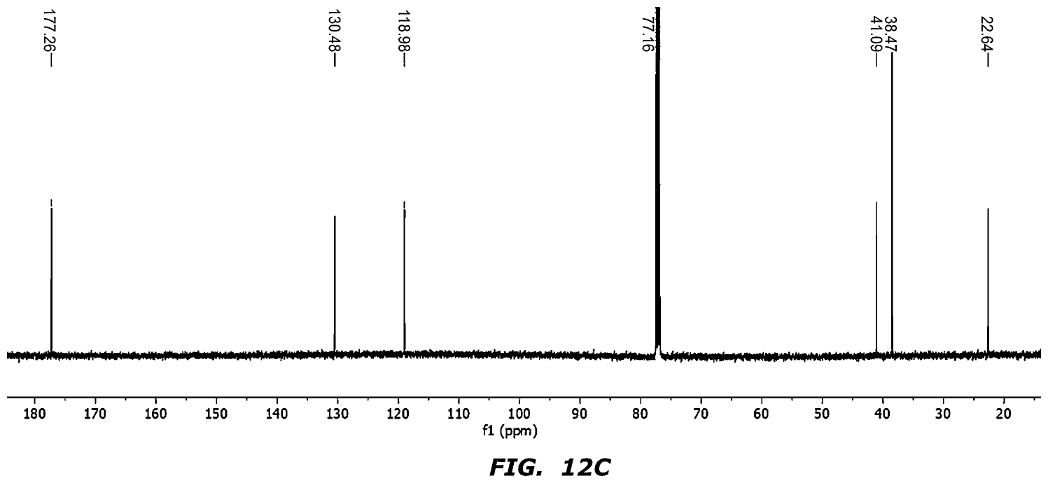

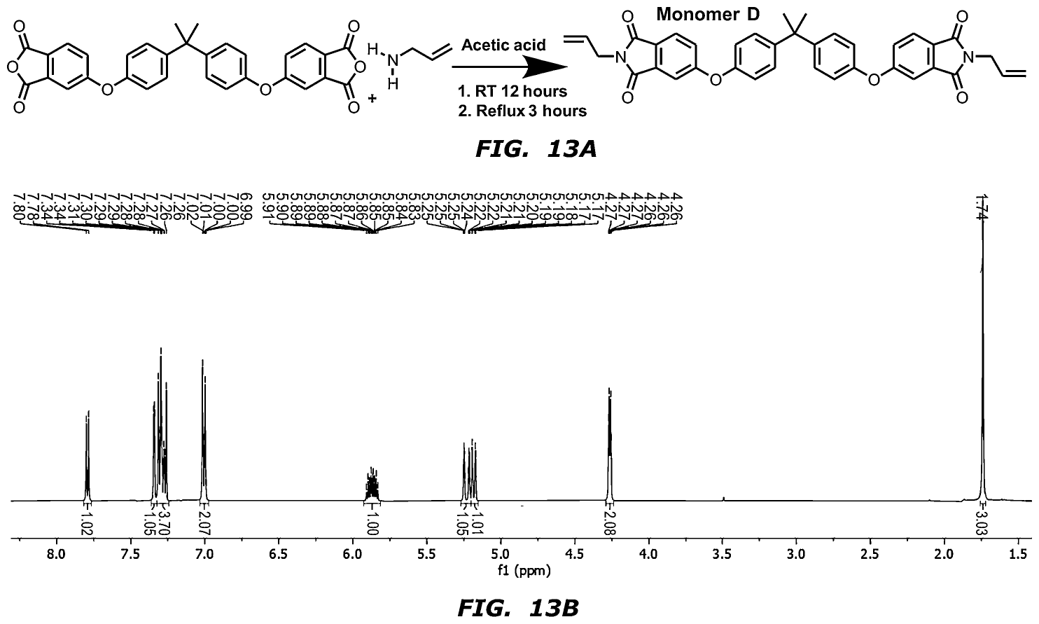

FIG. 12A schematically illustrates of an example synthesis used to produce PI cyclohexane. In a 1 L round bottom flask 20 grams (102 mmol) of 1,2,4,5-Cyclohexanetetracarboxylic dianhydride was suspended in 200 mL of DMF. The mixture was stirred while 15.65 mL (204 mmol) of allyl amine was added dropwise to the solution. The flask was stirred for 12 hours with mixture becoming clear. 200 mL of toluene was added to the mixture. The mixture was then refluxed for 9 hours with any remaining solids dissolved and water and toluene removed using Dean-Stark trap. The remaining toluene and DMF were removed using rotary evaporation. Viscous oil was dissolved in 150 mL of methanol and crystallized. Crystals were filtered and dried under vacuum at 80° C. for 12 hours to yield white crystals (19.0 g). Yield: 70%. M.P. 148° C. The product was analyzed with Fourier transform infrared (FTIR), ¹H-NMR, and ¹³C-NMR. FTIR (ATR): ν=3090, 2977, 2932, 2880 (C—H), 1762, 1683, 1645 (C═O), 1424, 1388, 1334, 1192 cm⁻¹. ¹H NMR (500 MHz, DMSO-d6): δ 5.81-5.70 (m, 2H), 5.24-5.15 (m, 4H), 4.07 (d, J=6.1 Hz, 4H), 2.93 (m, 4H), 2.69-2.60 (m, 2H), 1.55-1.41 (m, 2H). ¹³C NMR (126 MHz, CDCl₃): δ 177.01, 130.23, 118.73, 40.84, 38.22, 22.39. FTIR, ¹H-NMR, and ¹³C-NMR confirm successful synthesis of PI cyclohexane as shown in FIGS. 12B-12C.

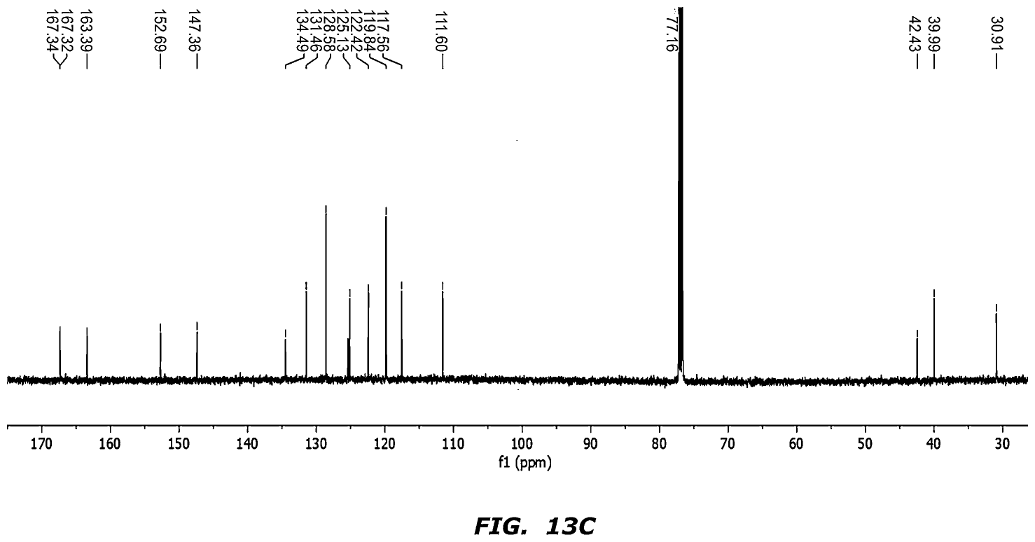

FIG. 13A schematically illustrates an example synthesis used to produce PI diether. In a 1 L round bottom flask 20 grams (38.4 mmol) of 4,4′-(4,4′-Isopropylidenediphenoxy)bis(phthalic anhydride) was suspended in 250 mL of acetic acid. The mixture was stirred while 5.75 mL (76.9 mmol) of allyl amine was added dropwise to the solution. The flask was stirred for 12 hours with mixture becoming clear. The mixture was then refluxed for 3 hours with any remaining solids dissolved. The flask was then cooled to room temperature and 250 mL of DI water added. Solids formed from adding water were filtered, rinsed with DI water. Solid was then recrystallized using 250 mL 1:1 mixture of methanol and acetone mixture and dried under vacuum at 70° C. for 12 hours to yield an off white powder (19.5 g). Yield: 85%. M.P. 94° C. The product was analyzed with Fourier transform infrared (FTIR), ¹H-NMR, and ¹³C-NMR. FTIR (ATR): ν=3062, 2965, 2929, 2874 (C—H), 1770, 1704 (C═O), 1601 (C═C), 1509, 1474, 1433, 1386, 1333 cm⁻¹. ¹H NMR (500 MHz, CDCl₃): δ 7.79 (d, J=8.2 Hz, 2H), 7.34-7.24 (m, 8H), 7.01 (d, J=8.3 Hz, 4H), 5.93-5.81 (m, 2H), 5.23-5.18 (m, 4H), 4.27 (d, J=5.6 Hz, 4H), 1.74 (s, 6H). ¹³C NMR (126 MHz, CDCl₃): δ 167.59, 163.64, 152.94, 147.62, 134.74, 131.71, 128.83, 125.64, 125.38, 122.67, 120.09, 117.81, 111.85, 42.69, 40.24, 31.16. FTIR, ¹H-NMR, and ¹³C-NMR confirm successful synthesis of PI diether as shown in FIGS. 13B-13C.

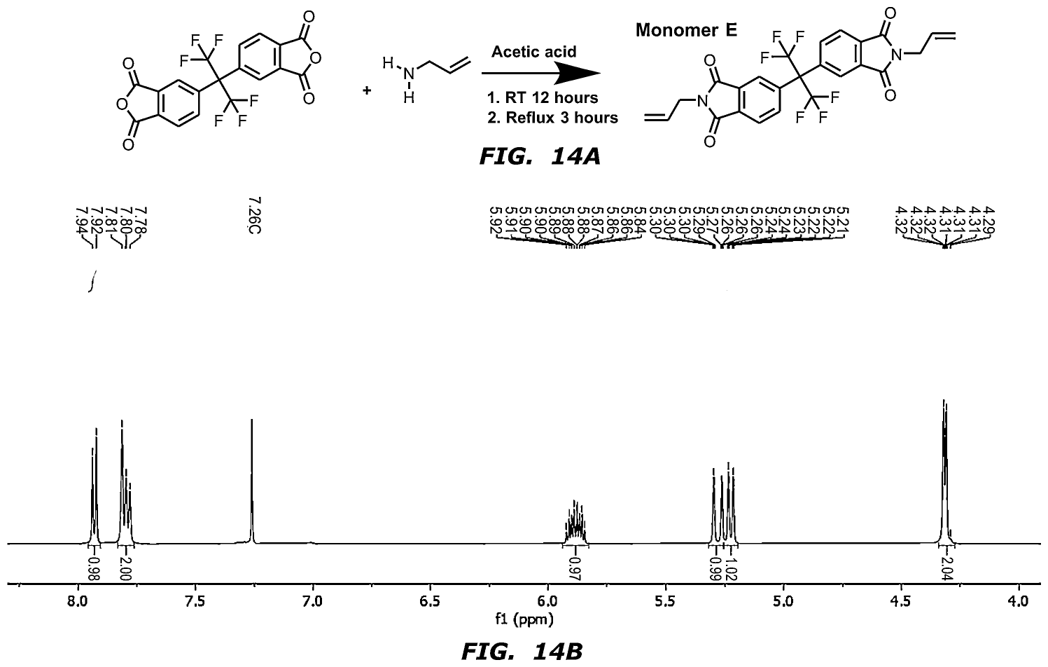

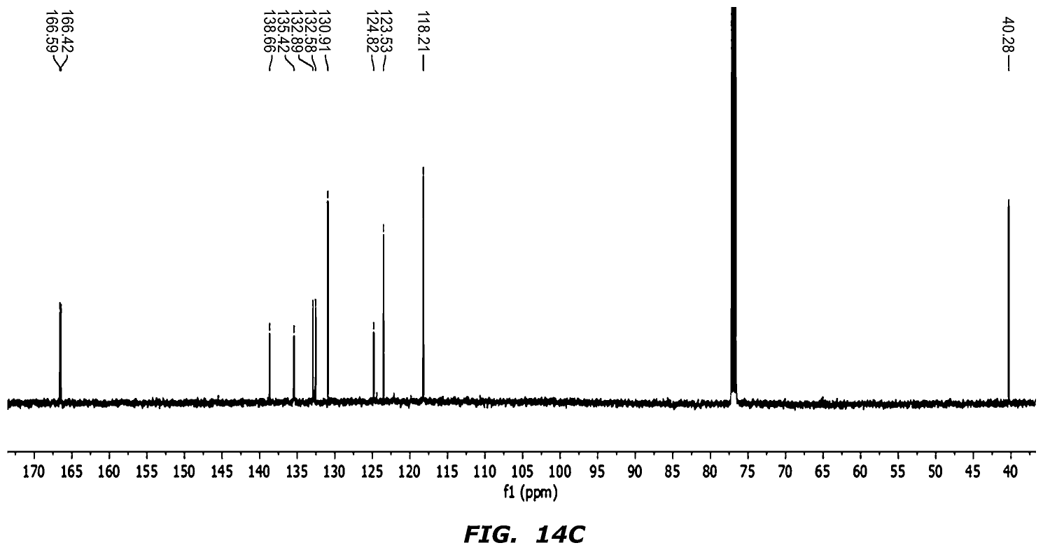

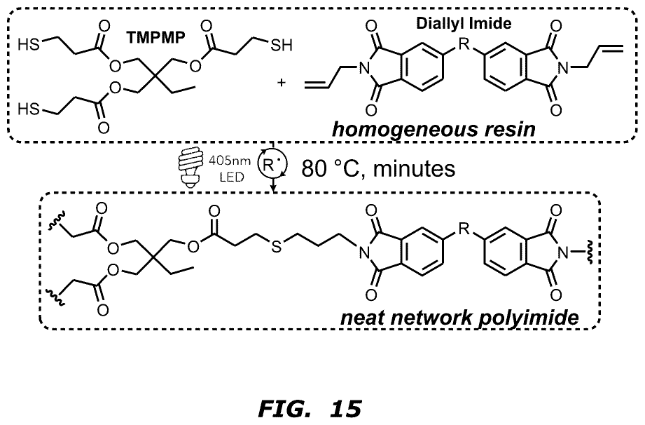

FIG. 14A schematically illustrates an example synthesis used to produce PI hexafluoro. In a 1 L round bottom flask 20 grams (45 mmol) of 4,4′-(Hexafluoroisopropylidene)diphthalic anhydride was suspended in 250 mL of acetic acid. The mixture was stirred while 6.74 mL (90 mmol) of allyl amine was added dropwise to the solution. The flask was stirred for 12 hours with mixture becoming clear. The mixture was then refluxed for 3 hours with any remaining solids dissolved. The flask was then cooled to room temperature and 250 mL of DI water added. The flask was again warmed to reflux or until solids were dissolved. Once the flask was cooled back to room temperature solids were filtered, rinsed with DI water. Solid was then recrystallized using 250 mL 1:1 mixture of methanol and acetone mixture and dried at 80° C. for 12 hours to yield a white powder (19.4 g). Yield: 82.4%. M.P. 157° C. The product was analyzed with Fourier transform infrared (FTIR), ¹H-NMR, and ¹³C-NMR. FTIR (ATR): ν=3090, 2930 (C—H), 1780, 1710 (C═O), 1620 (C═C), 1440, 1390, 1300, 1250 cm⁻¹. ¹H NMR (500 MHz, CDCl₃): δ 7.93 (d, J=7.9 Hz, 2H), δ 7.81 (s, 2H), 7.79 (d, J=8.0 Hz, 2H), 5.88 (m, 2H), 5.285-23 (m, 4H), 4.32 (d, J=5.7 Hz, 4H). ¹³C NMR (126 MHz, CDCl₃): δ 166.59, 138.66, 135.42, 132.89, 132.58, 130.91, 124.82, 123.53, 118.21, 40.28. FTIR, ¹H-NMR, and ¹³C-NMR confirm successful synthesis of PI hexafluoro as shown in FIGS. 14B-14C.

All polymerizations were carried out in a similar manner, regardless of the diallyl imide monomer 102 used. An exemplary polymerization utilizing PI cyclohexane is illustrated in FIG. 15. 1 gram (3.3 mmol) of cyclohexane monomer, 0.834 grams (2.1 mmol) of trimethylolpropane tris(3-mercaptopropionate) (TMPMP), and 0.018 grams (0.052 mmol) of TPO were added to cantillation vial. The vial was warmed slowly to melt the cyclohexane monomer and mixed. Melted resin was then added to preheated molds in an 80° C. Form Cure UV curing oven. The samples were cured for 10 minutes at 405 nm wavelength with 5 mW/cm² light intensity (measured by Thorlabs PM100D optical power meter equipped with a standard photodiode S120VC sensor).

Without departing from the spirit and scope of this invention, one of ordinary skill can make various modifications to the invention to adapt it to various usages and conditions. As such, these changes and modifications are properly, equitably, and intended to be, within the full range of equivalence of the following claims,

What is claimed is:

1. A degradable polyimide substrate formed from a crosslinked polymer that contains one or more thioether linkages and one or more imide linkages in repeating units of the polymer, wherein the thioether linkages and the imide linkages are introduced by polymerizing from:
one or more alkene monomers;
one or more thiol monomers; and
wherein thioether linkages are present between polymerization residues of the one or more alkene monomers and the one or more thiol monomers,
wherein the one or more alkene monomers and the one or more thiol monomers polymerize to form the degradable polyimide substrate, and
wherein the one or more thiol monomers comprise ester linkages, wherein the ester linkages are degradable under mild conditions.

2. The degradable polyimide substrate of claim 1, wherein the one or more alkene monomers comprise at least one of allyl ether, vinyl ether, allyl ester, norbornene, acrylate, methacrylate, epoxy, diallyl imide monomers, diallyl imide ether monomers, diallyl imide diether monomers, diallyl imide cyclohexane monomers, diallyl imide hexafluoro monomers, or diallyl imide ester monomers.

3. The degradable polyimide substrate of claim 1, wherein the one or more thiol monomers comprise at least one of trimethylolpropane tris 3-mercaptopropionate (TMPMP), ethylene glycol di(3-mercaptopropionate) (GDMP), or pentaerythritol tetra(3-mercaptopropionate) (PETMP).

4. The degradable polyimide substrate of claim 1, wherein the one or more alkene monomers have a melting point of less than about 220° C., less than about 200° C., less than about 150° C., or less than about 100° C.

5. The degradable polyimide substrate of claim 1, wherein the polymer substrate is cross-linked.

6. The degradable polyimide substrate of claim 1, wherein the polymer substrate has a glass transition temperature from about −100° C. to about 250° C., from about −50° C. to about 200° C., from about 50° C. to about 150° C., from about 50° C. to about 150° C., or from about 60° C. to about 100° C.

7. The degradable polyimide substrate of claim 1, wherein the polymer substrate has a Young's modulus of at least about 1000 MPa, at least about 1050 MPa, at least about 1100 MPa, at least about 1150 MPa, no more than about 2500 MPa, no more than about 2000 MPa, no more than about 1500 MPa, no more than about 1400 MPa, no more than about 1300 MPa, or no more than about 1250 MPa.

8. The degradable polyimide substrate of claim 1, wherein the polymer substrate has a tensile strength of at least about 30 mPa, at least about 35 MPa, at least about 40 MPa, or at least about 45 MPa, no more than about 100 MPa, no more than about 80 MPa, or no more than about 75 MPa.

9. The degradable polyimide substrate of claim 1, wherein the polymer substrate is degraded using a transesterification reaction stimulated at or near ambient temperature.

10. The degradable polyimide substrate of claim 9, wherein the transesterification reaction is stimulated with a methanol or other alcohol solution, optionally comprising about 50% by weight dichloromethane (DCM), and wherein potassium carbonate (K₂CO₃), another alkali metal carbonate, alkali metal hydroxide, or organic base is used as a catalyst.

11. A method of synthesizing and curing a degradable polyimide substrate, the method comprising:
providing diallyl imide or other alkene monomers and thiol monomers in a container;
heating the diallyl imide or other alkene and thiol monomers to form a liquid resin comprising melted diallyl imide or other alkene monomers and melted thiol monomers;
transferring the liquid resin to heated molds; and
curing the liquid resin with UV light, visible light, heat, and/or a thermal radical generating catalyst.

12. The method of claim 11, wherein the liquid resin remains liquid for an amount of time sufficient to transfer the liquid resin from the container to the heated molds.

13. A multimodulus polymer substrate comprising:
diallyl imide or other alkene monomer polymerization residues;
thiol monomer polymerization residues;
epoxy monomer polymerization residues;
thioether linkages between the diallyl imide or other alkene monomer polymerization residues and the thiol monomer polymerization residues, thiol-epoxy linkages between the thiol monomer polymerization residues and the epoxy monomer polymerization residues, and epoxy-epoxy linkages between the epoxy monomer polymerization residues,
wherein the thiol-epoxy linkages provide the polymer substrate with flexibility and the epoxy-epoxy linkages provide the polymer substrate with stiffness.

14. A method of synthesizing and curing a multimodulus polymer substrate, the method comprising:
providing diallyl imide or other alkene monomers, thiol monomers, and epoxy monomers;
heating the monomers to produce a liquid resin comprising melted diallyl imide or other alkene monomers, melted thiol monomers, and melted epoxy monomers;
photocuring the resin with a photodosage of UV or visible light to form thioether linkages;
thermal curing the resin at a first temperature to form thiol-epoxy linkages; and
thermal curing the resin at a second temperature to form epoxy-epoxy linkages,
wherein varying the photodosage of UV or visible light varies an amount of unreacted thiol groups in the resin and wherein the amount of unreacted thiol groups in the resin varies an amount of unreacted epoxy groups in the resin.

15. The method of claim 14, wherein the photodosage is from about 0 mJ to about 70 mJ/cm², and wherein a flexible polymer substrate is produced.

16. The method of claim 14, wherein the photodosage is from about 70 mJ to about 175 mJ/cm², and wherein a firm or stiff polymer substrate is produced.

17. A method of manufacturing flexible electronics, the method comprising:
depositing and curing a first degradable polyimide film;
depositing one or more electronic components on the first degradable polyimide film, the electronic components forming a circuit; and
depositing and curing a second degradable polyimide film over the electronic components,
wherein the method is repeatable to form a multilayered circuit, and
wherein the degradable polyimide films can be dissolved without harming the electronic components.

18. The method of claim 17, wherein the first degradable film and the second degradable film are selectively cured, and wherein the uncured portions of the first degradable film and the second degradable film can be removed to form one or more electrical vias.

19. The method of claim 18, wherein the one or more electrical vias connect circuits of different layers of a multilayered circuit.

20. The method of claim 17, wherein the first degradable film and the second degradable film comprise:
diallyl imide or other alkene monomer polymerization residues;
thiol monomer polymerization residues; and
thioether linkages between the diallyl imide or other alkene monomer polymerization residues and the thiol monomer polymerization residues,
wherein the diallyl imide or other alkene monomer polymerization residues and the thiol monomer polymerization residues are polymerized to form the flexible polymer substrate, and
wherein the thiol monomer polymerization residues comprise ester linkages, wherein the ester linkages are degradable under mild conditions.
